(19) United States
(12) Patent Application Publication
(10) Pub. No.: US 2026/0026086 A1
(43) Pub. Date: Jan. 22, 2026

(54) SEMICONDUCTOR DEVICE

(71) Applicant: Samsung Electronics Co., Ltd., Suwon-si (KR)

(72) Inventors: Jin-Hwan KIM, Suwon-si (KR); In Jun HWANG, Suwon-si (KR)

(73) Assignee: Samsung Electronics Co., Ltd., Suwon-si (KR)

(21) Appl. No.: 19/018,489

(22) Filed: Jan. 13, 2025

(30) Foreign Application Priority Data
Jul. 22, 2024 (KR) 10-2024-0096441

(51) Int. Cl. H10D 84/82; H01L 23/00; H03F 3/16; H10D 30/47; H10D 62/10; H10D 62/81; H10D 62/815; H10D 64/23

(52) U.S. Cl. CPC H10D 84/82; H01L 24/48; H10D 30/471; H10D 62/102; H10D 62/812; H10D 62/8164; H10D 64/256; H01L 2224/48227; H01L 2924/13064; H03F 3/165

(57) ABSTRACT

A semiconductor device includes first and second transistors on a substrate of first conductivity type, and a well region between at least one of the first and second transistors and the substrate, and has second conductivity type different from first conductivity type. The first transistor includes a first channel layer on the substrate, a first barrier layer on the first channel layer, a first gate electrode on the first barrier layer, and a first source electrode and a first drain electrode on opposite sides of the first gate electrode, and connected to the first channel layer. The second transistor includes a second channel layer on the substrate, a second barrier layer on the second channel layer, a second gate electrode on the second barrier layer, and a second source electrode and a second drain electrode on opposite sides of the second gate electrode, and connected to the second channel layer.

### CROSS-REFERENCE TO RELATED APPLICATION

This application claims priority under 35 U.S.C. § 119 to Korean Patent Application No. 10-2024-0096441 filed in the Korean Intellectual Property Office on Jul. 22, 2024, the entire contents of which are incorporated herein by reference.

### BACKGROUND

Example embodiments are directed to a semiconductor device.

Power semiconductor devices are used in transportation, for example, in electric vehicles, trains, and electric trams, renewable energy systems, for example, in solar power generation and wind power generation, and/or mobile devices. Power semiconductor devices handle relatively higher voltage and/or higher current, and, and perform power conversion and control in higher power systems and high-power electronic devices. Power semiconductor devices are designed to handle high power including relatively large current and/or voltages. For example, power semiconductor devices can handle voltages of hundreds to thousands of volts and/or currents of tens to thousands of amperes. Power semiconductor devices can improve the efficiency of electrical energy consumption by reducing power losses. Further, power semiconductor devices operate with relatively higher stability in high temperature environments.

Power semiconductor devices can be categorized, for example, as SiC power semiconductor devices and GaN power semiconductor devices. Power semiconductor devices including SiC or GaN provide improved stability at higher temperatures. SiC power semiconductor devices can operate at relatively higher temperatures and have relatively lower power loss, and can be used electric vehicles, renewable energy systems, and the like. GaN power semiconductor devices can operate at higher frequency or speed, and can be used for fast charging of mobile devices and the like.

### SUMMARY

Some example embodiments are directed to a semiconductor device including two high electron mobility transistors connected in series between a first power voltage and a second power voltage lower than the first power voltage on a single substrate.

A semiconductor device, according to some example embodiments, includes a substrate of a first conductivity type, a first transistor and a second transistor that are positioned on the substrate, and a well region that is positioned between at least one of the first transistor and the second transistor and the substrate, and has a second conductivity type different from the first conductivity type. The first transistor includes a first channel layer that is positioned on the substrate, a first barrier layer that is positioned on the first channel layer, a first gate electrode that is positioned on the first barrier layer, and a first source electrode and a first drain electrode that are positioned on opposite sides of the first gate electrode, and are connected to the first channel layer. The second transistor includes a second channel layer that is positioned on the substrate, a second barrier layer that is positioned on the second channel layer, a second gate electrode that is positioned on the second barrier layer, and a second source electrode and a second drain electrode that are positioned on opposite sides of the second gate electrode, and are connected to the second channel layer. The first drain electrode is connected to a first power voltage, and the second source electrode is connected to a second power voltage, and the first source electrode and the second drain electrode are connected to each other, and at least one of the first source electrode and the second source electrode is connected to the well region.

A semiconductor device, according to some example embodiments, includes a substrate of a first conductivity type, a first transistor and a second transistor that are positioned on the substrate, and a well region that is positioned between the substrate and the first transistor and has a second conductivity type different from the first conductivity type. The first transistor includes a first channel layer that is positioned on the substrate, a first barrier layer that is positioned on the first channel layer, a first gate electrode that is positioned on the first barrier layer, and a first source electrode and a first drain electrode that are positioned on opposite sides of the first gate electrode, and are connected to the first channel layer. The second transistor includes a second channel layer that is positioned on the substrate, a second barrier layer that is positioned on the second channel layer, a second gate electrode that is positioned on the second barrier layer, and a second source electrode and a second drain electrode that are positioned on opposite sides of the second gate electrode, and are connected to the second channel layer. The first drain electrode is connected to a first power voltage, and the second source electrode is connected to a second power voltage lower than the first power voltage, and the first source electrode and the second drain electrode are connected to the well region.

A semiconductor device, according to some example embodiments, includes a substrate of a first conductivity type, a first transistor and a second transistor that are positioned on the substrate, and a well region that is positioned between the substrate and the first transistor and has a second conductivity type different from the first conductivity type. The first transistor includes a first channel layer that is positioned on the substrate, a first barrier layer that is positioned on the first channel layer, a first gate electrode that is positioned on the first barrier layer, and a first source electrode and a first drain electrode that are positioned on opposite sides of the first gate electrode, and are connected to the first channel layer. The second transistor includes a second channel layer that is positioned on the substrate, a second barrier layer that is positioned on the second channel layer, a second gate electrode that is positioned on the second barrier layer, and a second source electrode and a second drain electrode that are positioned on opposite sides of the second gate electrode, and are connected to the second channel layer. The first drain electrode is connected to a first power voltage, and the second source electrode is connected to a second power voltage lower than the first power voltage, and the first source electrode and the second drain electrode are connected to each other. The well region includes a first well region that is positioned between the substrate and the first source electrode and a second well region that is positioned between the substrate and the first drain electrode, and the first well region and the second well region are spaced apart from each other. The first source electrode is connected to the first well region, and the first drain electrode is connected to the second well region.

According to some example embodiments, two high electron mobility transistors are formed on a single substrate and are connected in series between a first power voltage and a second power voltage lower than the first power voltage. The operation reliability of the high electron mobility transistors is improved.

### BRIEF DESCRIPTION OF THE DRAWINGS

FIG. 1 is a circuit diagram illustrating a semiconductor device according to some example embodiments.

FIG. 2 is a cross-sectional view illustrating a high electron mobility transistor (HEMT) of the semiconductor device according to some example embodiments.

FIG. 3 is a plan view illustrating an amplifier circuit of the semiconductor device according to some example embodiments.

FIG. 4 is a cross-sectional view taken along line I-I′ of FIG. 3.

FIG. 5 is a cross-sectional view illustrating an amplifier circuit of a semiconductor device according to some example embodiments.

FIG. 6 is a cross-sectional view illustrating an amplifier circuit of a semiconductor device according to some example embodiments.

FIG. 7 is a plan view illustrating a semiconductor device according to some example embodiments.

FIG. 8 is a cross-sectional view taken along line II-II′ of FIG. 7.

FIG. 9 is a plan view illustrating an amplifier circuit of a semiconductor device according to some example embodiments.

FIG. 10 is a cross-sectional view taken along line III-III′ of FIG. 9.

FIG. 11 is a plan view illustrating an amplifier circuit of a semiconductor device according to some example embodiments.

FIG. 12 is a cross-sectional view taken along line IV-IV′ of FIG. 11.

FIG. 13 is a cross-sectional view illustrating an amplifier circuit of a semiconductor device according to some example embodiments.

FIG. 14 is a cross-sectional view illustrating an amplifier circuit of a semiconductor device according to some example embodiments.

### DETAILED DESCRIPTION

In the following detailed description, some example embodiments have been shown and described based on the accompanying drawings. The example embodiments are not limited to the discussion herein and may be implemented in various other ways without departing from the spirit and scope of the disclosure.

The drawings and description are to be regarded as illustrative in nature and not restrictive. Like reference numerals designate like elements throughout the specification.

In addition, the size and thickness of each configuration shown in the drawings are arbitrarily shown for understanding and ease of description, and example embodiments are not limited thereto. In the drawings, the thickness of layers, films, panels, regions, etc., are exaggerated for clarity. Further, in the drawings, for understanding and ease of description, the thickness of some layers and areas is exaggerated.

Further, it will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is “on” a reference portion, the element is located above or below the reference portion, and it does not necessarily mean that the element is located “above” or “on” in a direction opposite to gravity.

In addition, unless explicitly described to the contrary, the word “comprise”, and variations such as “comprises” or “comprising”, will be understood to imply the inclusion of stated elements but not the exclusion of any other elements.

Further, in the entire specification, when it is referred to as “on a plane”, it means when a target part is viewed from above, and when it is referred to as “on a cross-section”, it means when the cross-section obtained by cutting a target part vertically is viewed from the side.

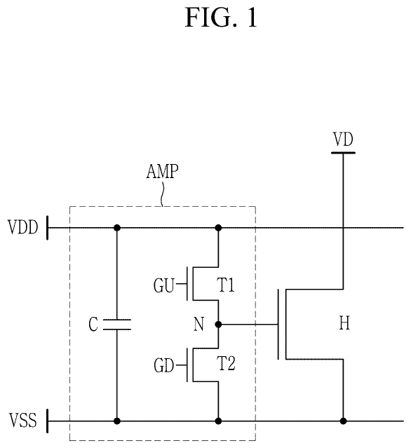

Hereinafter, a semiconductor device according to some example embodiments will be described with reference to FIGS. 1 to 4.

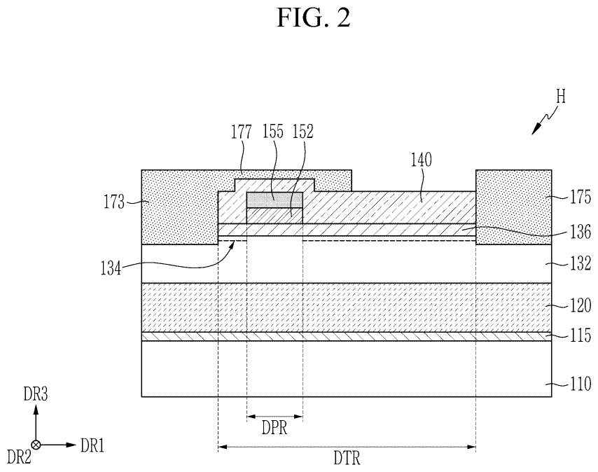

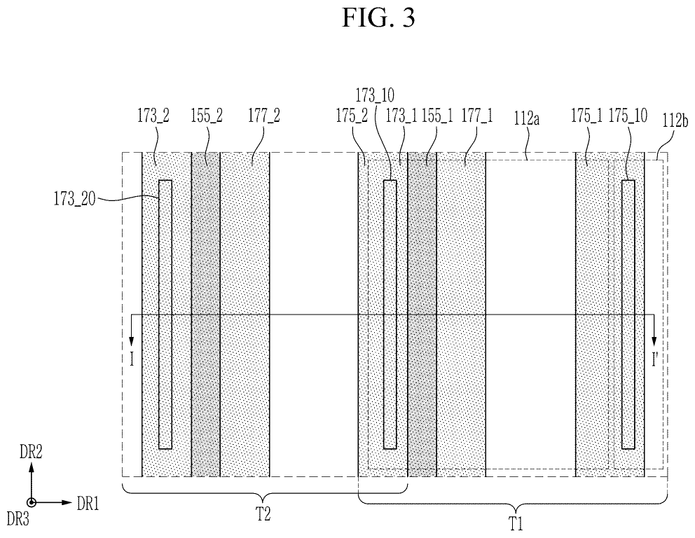

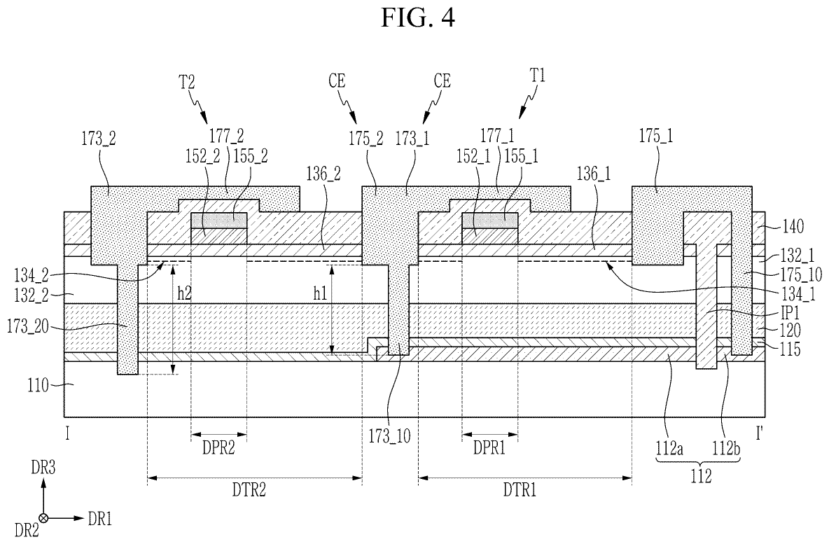

FIG. 1 is a circuit diagram illustrating a semiconductor device according to some example embodiments. FIG. 2 is a cross-sectional view illustrating a high electron mobility transistor (HEMT) of the semiconductor device according to some example embodiments. FIG. 3 is a plan view illustrating an amplifier circuit of the semiconductor device according to some example embodiments. FIG. 3 illustrates the source electrodes, drain electrodes, and gate electrodes of transistors constituting the amplifier circuit according to some example embodiments, and the other constituent elements are omitted in the drawings for the sake of clarity of illustration. FIG. 4 is a cross-sectional view taken along line I-I′ of FIG. 3.

Referring to FIG. 1, the semiconductor device may be a power semiconductor device for converting, controlling, and/or distributing supplied power, and may include a high electron mobility transistor H and an amplifier circuit AMP connected thereto. The power semiconductor device may operate at high power. The amplifier circuit AMP may amplify a control signal received from an external source (for example, an integrated circuit included outside or inside the semiconductor device). The control signal may output relatively smaller power for driving the power semiconductor device. The amplifier circuit AMP may generate a gate signal by amplifying the control signal, and may supply the gate signal to the high electron mobility transistor H. The high electron mobility transistor H may be an individual device constituting the power semiconductor device (for example, an inverter, a converter, a power management IC (PMIC), and/or a power distribution unit (PDU)) for performing a function of converting, controlling, and/or distributing supplied power.

The high electron mobility transistor H may perform a switching operation based on the gate signal received from the amplifier circuit AMP. The gate signal may be an electrical signal which is provided to a terminal of the high electron mobility transistor H. For example, the gate signal may be a voltage (or current) which is supplied to the gate electrode of the high electron mobility transistor H. The high electron mobility transistor H may perform an on/off operation in response to the gate signal which is applied to the gate electrode. The semiconductor device may convert, control, and/or distribute supplied power by controlling the on/off operation of the high electron mobility transistor H.

FIG. 1 illustrates that a single high electron mobility transistor H is connected to the amplifier circuit AMP; however, example embodiments are not limited thereto. In some example embodiments, a plurality of high electron mobility transistors may be connected to the amplifier circuit AMP. For example, a plurality of high electron mobility transistors may be connected in parallel with one another. Also, besides transistors, other individual devices for performing a switching operation, such as diodes and thyristors, may be connected to the amplifier circuit AMP.

The amplifier circuit AMP may include a first transistor T1 and a second transistor T2 connected in series, and a capacitor C connected in parallel with the first transistor T1 and the second transistor T2. The drain electrode of the first transistor T1 and a first electrode of the capacitor C may be connected to a first power voltage VDD. The first power voltage VDD may be connected to a power source. The first power voltage VDD may be supplied from the power source. The source electrode of the second transistor T2 and a second electrode of the capacitor C may be connected to a second power voltage VSS. The second power voltage VSS may have a voltage level lower than that of the first power voltage VDD. For example, the second power voltage VSS may be connected to a ground. However, in some other example embodiments, and the second power voltage VSS may have a negative voltage level, or may have a positive voltage level lower than that of the first power voltage VDD. The source electrode of the first transistor T1 and the drain electrode of the second transistor T2 may be connected to an output node N.

Since the first transistor T1 is connected to the relatively higher voltage as compared to the second transistor T2 and the second transistor T2 is connected to the relatively lower voltage as compared to the first transistor T1, hereinafter, the first transistor T1 may be referred to as the high-side transistor, and the second transistor T2 may be referred to as the low-side transistor.

The drain electrode of the high electron mobility transistor H may be connected to a third power voltage VD, and the source electrode thereof may be connected to the second power voltage VSS. The third power voltage VD may have a voltage level higher than those of the first power voltage VDD and the second power voltage VSS. The gate electrode of the high electron mobility transistor H may be connected to the output node N of the amplifier circuit AMP.

For example, the first transistor T1 may be a pull-up transistor, and the second transistor T2 may be a pull-down transistor. A pull-up signal GU may be applied to the gate electrode of the first transistor T1, and a pull-down signal GD may be applied to the gate electrode of the second transistor T2. The pull-up signal GU and the pull-down signal GD may be complementary. When the pull-up signal GU has a first level, the pull-down signal GD may have a second level lower than the first level. When the pull-up signal GU has the second level, the pull-down signal GD may have the first level higher than the second level. The first level is a voltage which turns on the first transistor T1 or the second transistor T2, and the second level may be a voltage which turns off the first transistor T1 or the second transistor T2.

When the pull-up signal GU having the first level is applied to the first transistor T1 and the pull-down signal GD having the second level is applied to the second transistor T2, the first power voltage VDD may be applied to the gate electrode of the high electron mobility transistor H. Since the first power voltage VDD has the voltage level higher than that of the threshold voltage of the high electron mobility transistor H, the high electron mobility transistor H may be turned on.

When the pull-up signal GU having the second level is applied to the first transistor T1 and the pull-down signal GD having the first level is applied to the second transistor T2, the gate electrode of the high electron mobility transistor H may be connected to the second power voltage VSS. In other words, charge accumulated in the gate electrode of the high electron mobility transistor H may migrate to the second power voltage VSS through the second transistor T2, and the high electron mobility transistor H may be turned off.

The capacitor C may be a decoupling capacitor. For example, when the high electron mobility transistor H is turned off, the voltage of the gate electrode of the high electron mobility transistor H may rapidly drop to the same level as that of the second power voltage VSS. The capacitor C may maintain the voltage of the drain electrode of the first transistor T1 at the same level as that of the power voltage VDD without being affected by the voltage of the gate electrode of the high electron mobility transistor H. For example, when the high electron mobility transistor H is turned on, the voltage stored in the capacitor C may be supplied as the voltage of the drain electrode of the first transistor T1. In this case, a constant voltage (for example, a voltage corresponding to the potential difference between the first power voltage VDD and the second power voltage VSS) may be supplied as the voltage of the drain electrode of the first transistor T1, regardless of the state (on/off) of the high electron mobility transistor H.

FIG. 1 illustrates that one high electron mobility transistor H is connected to the amplifier circuit AMP; however, example embodiments are not limited thereto. A plurality of high electron mobility transistors may be connected to the amplifier circuit AMP. The plurality of high electron mobility transistors may be connected in parallel with each another. The drain electrode of each of the plurality of high electron mobility transistors may be commonly connected to the third power voltage VD, and the source electrode of each of the plurality of high electron mobility transistors may be commonly connected to the second power voltage VSS. Gate signals having substantially the same level may be provided to the gate electrodes of the plurality of high electron mobility transistors, respectively, substantially at the same time, whereby it may be possible to improve the reliability of a switching operation which is performed by one unit block including the plurality of high electron mobility transistors.

Referring to FIG. 2, the high electron mobility transistor H may include a channel layer 132, a barrier layer 136 that is positioned on the channel layer 132, a gate electrode 155 that is positioned on the barrier layer 136, and a source electrode 173 and a drain electrode 175 that are positioned on opposite sides of the gate electrode 155 on the channel layer 132.

The channel layer 132 may be a layer that forms a channel between the source electrode 173 and the drain electrode 175, and within the channel layer 132, a 2-dimensional electron gas (2DEG) 134 may be positioned. The 2-dimensional electron gas 134 is a charge transfer model that is used in solid-state physics, and may indicate a plurality of electrons that are confined or packed in two dimensions (for example, in directions on an x-y plane) such that they are free to migrate in the two dimensions but are limited from migrating in the third dimensions (for example, in a z direction). In other words, the 2-dimensional electron gas 134 may be in a form like a two-dimensional sheet in a three-dimensional space. Such a 2-dimensional electron gas 134 may be seen in a semiconductor heterojunction structure, and in the high electron mobility transistor H according to some example embodiments, the 2-dimensional electron gas 134 may be present at the interface between the channel layer 132 and the barrier layer 136. For example, the 2-dimensional electron gas 134 may be present at a portion inside the channel layer 132 adjacent to the barrier layer 136. The channel layer 132 may be or include at least one material selected from III-V materials such as nitrides containing Al, Ga, In, B, or a combination thereof. The channel layer 132 may include a single layer or multiple layers. The channel layer 132 may be formed of AlₓIn_{y}Ga_{1-x-y}N (wherein 0≤x≤1, 0≤y≤1, and x+y≤1). For example, the channel layer 132 may be or include AlN, GaN, InN, InGaN, AlGaN, AlInN, AlInGaN, or a combination thereof. The channel layer 132 may be a layer doped with impurities, or may be a layer undoped with impurities. The thickness of the channel layer 132 may be about hundreds of nm or less.

The channel layer 132 may be positioned on a substrate 110. The substrate 110 may be or include a semiconductor material. For example, the substrate 110 may be or include Si. For example, the substrate 110 may be a p-type Si substrate doped with a p-type impurity, but is not limited thereto. In some example embodiments, the substrate 110 may be an n-type Si substrate doped with an n-type impurity.

Between the substrate 110 and the channel layer 132, a seed layer 115 and a buffer layer 120 may be positioned. The substrate 110, the seed layer 115, and/or the buffer layer 120 may form or otherwise define the channel layer 132. In some example embodiments, when a substrate made of GaN is used as the channel layer 132, at least one of the substrate 110, the seed layer 115, and the buffer layer 120 may be omitted, depending on application and/or design. In some example embodiments, a substrate 110 made of Si may be used to grow a channel layer 132 including GaN. In this case, since the lattice structure of Si and the lattice structure of GaN are different, it may be challenging to grow the channel layer 132 directly on the substrate 110. Therefore, a seed layer 115 and a buffer layer 120 may be first grown on the substrate 110, and then the channel layer 132 may be grown on the buffer layer 120. Also, in some example embodiments, at least one of the substrate 110, the seed layer 115, and the buffer layer 120 may be removed from the final structure of the high electron mobility transistor H after being used in the manufacturing process.

The seed layer 115 may be positioned directly on the substrate 110. However, in some example embodiments, between the substrate 110 and the seed layer 115, other predetermined layers may be further positioned or formed. The seed layer 115 may function as a seed for growing the buffer layer 120, and may be formed of a crystal lattice structure that may be used as a seed for the buffer layer 120. The buffer layer 120 may be positioned directly on the seed layer 115. However, in some example embodiments, and one or more other desired layers may be further positioned or formed between the seed layer 115 and the buffer layer 120. The seed layer 115 may be or include at least one material selected from III-V materials such as nitrides containing Al, Ga, In, B, or a combination thereof. The seed layer 115 may be formed of AlₓIn_{y}Ga_{1-x-y}N (wherein 0≤x≤1, 0≤y≤1, and x+y≤1). For example, the seed layer 115 may be or include AlN, GaN, InN, InGaN, AlGaN, AlInN, AlInGaN, or a combination thereof.

The buffer layer 120 may be positioned on the seed layer 115. The buffer layer 120 may be positioned between the seed layer 115 and the channel layer 132. The buffer layer 120 may be a layer for mitigating, reducing or minimizing differences or mismatch in lattice constant and thermal expansion coefficient between the seed layer 115 and the channel layer 132 and/or limiting, reducing or minimizing parasitic current (leakage current) from flowing through the channel layer 132. The buffer layer 120 may include at least one material selected from III-V materials such as nitrides containing Al, Ga, In, B, or a combination thereof. The buffer layer 120 may be formed of AlₓIn_{y}Ga_{1-x-y}N (wherein 0≤x≤1, 0≤y≤1, and x+y≤1). For example, the buffer layer 120 may be or include AlN, GaN, InN, InGaN, AlGaN, AlInN, AlInGaN, or a combination thereof.

The buffer layer 120 of the high electron mobility transistor H may include a superlattice layer that is positioned on the seed layer 115, and a high-resistivity layer that is positioned on the superlattice layer. The superlattice layer and the high-resistivity layer may be sequentially positioned on the substrate 110.

The superlattice layer may be positioned on the seed layer 115. The superlattice layer may be positioned directly on the seed layer 115. However, in some example embodiments, and one or more other desired layers may be further positioned or formed between the seed layer 115 and the superlattice layer. The superlattice layer is a layer for minimizing or reducing differences in lattice constant and thermal expansion coefficient between the substrate 110 and the channel layer 132, thereby relieving tensile stress and compressive stress that may be generated between the substrate 110 and the channel layer 132 and relieving stress between layers formed by growth in the final structure of the high electron mobility transistor H, according to some example embodiments. The superlattice layer may include at least one material selected from III-V materials such as nitrides containing Al, Ga, In, B, or a combination thereof. The superlattice layer may be formed of AlₓIn_{y}Ga_{1-x-y}N (wherein 0≤x≤1, 0≤y≤1, and x+y≤1). For example, the superlattice layer may be or include AlN, GaN, InN, InGaN, AlGaN, AlInN, AlInGaN, or a combination thereof.

In some example embodiments, the superlattice layer may include multiple layers of different materials and alternately stacked. For example, the superlattice layer may have a structure in which layers of AlGaN and layers of AlN are alternately stacked. In other words, AlGaN, AlN, AlGaN, AlN, AlGaN, and AlN are sequentially stacked to form the superlattice layer. The number of AlGaN layers and AlN layers which constitute the superlattice layer may be changed, and the materials which constitute the superlattice layer may be changed, depending on application and/or design. In some example embodiments, the superlattice layer may have a structure in which layers of AlGaN and layers of GaN may be alternately stacked. In other words, AlGaN, GaN, AlGaN, GaN, AlGaN, and GaN may be sequentially stacked to form the superlattice layer. In some example embodiments, when the superlattice layer includes GaN, InN, AlGaN, AlInN, InGaN, AlN, AlInGaN, a combination thereof, etc., the superlattice layer may have an n-type semiconductor characteristic in which the concentration of electrons may be greater than the concentration of holes; however, example embodiments are not limited thereto.

The high-resistivity layer may be positioned on the superlattice layer. The high-resistivity layer may be positioned directly on the superlattice layer. However, in some example embodiments, and one or more other desired layers may be formed between the superlattice layer and the high-resistivity layer. The high-resistivity layer may be positioned or otherwise formed between the superlattice layer and the channel layer 132. The high-resistivity layer may be a layer for limiting, reducing, or minimizing leakage current from flowing through the channel layer 132, thereby limiting, reducing, or minimizing the high electron mobility transistor H, according to some example embodiments, from deterioration. The high-resistivity layer may include a material having low conductivity such that the substrate 110 and the channel layer 132 can be electrically insulated from each other. The high-resistivity layer may be or include at least one material selected from III-V materials such as nitrides including Al, Ga, In, B, or a combination thereof. The high-resistivity layer may be formed of AlₓIn_{y}Ga_{1-x-y}N (wherein 0≤x≤1, 0≤y≤1, and x+y≤1). For example, the high-resistivity layer may be or include AlN, GaN, InN, InGaN, AlGaN, AlInN, AlInGaN, or a combination thereof. The high-resistivity layer may be or include a single layer or multiple layers.

The barrier layer 136 may be positioned on the channel layer 132. The barrier layer 136 may be positioned directly on the channel layer 132. However, in some example embodiments, and one or more other desired layers may be positioned between the channel layer 132 and the barrier layer 136. A region of the channel layer 132 overlapping the barrier layer 136 between the source electrode 173 and the drain electrode 175 may be referred to as a drift region DTR. The drift region DTR may be positioned between the source electrode 173 and the drain electrode 175. The drift region DTR may refer to a region in which carriers migrate in presence of a potential difference occurs between the source electrode 173 and the drain electrode 175.

The high electron mobility transistor H according to some example embodiments may be turned on and off according to at least one of whether voltage is applied to the gate electrode 155 and the magnitude of voltage which is applied to the gate electrode 155, whereby migration of carriers in the drift region DTR may be enabled or permitted, or mitigated or reduced.

The barrier layer 136 may be or include at least one material selected from III-V materials such as nitrides containing Al, Ga, In, B, or a combination thereof. The barrier layer 136 may be formed of AlₓIn_{y}Ga_{1-x-y}N (wherein 0≤x≤1, 0≤y≤1, and x+y≤1). The barrier layer 136 may be or include GaN, InN, AlGaN, AlInN, InGaN, AlN, AlInGaN, a combination thereof, etc. The energy band gap of the barrier layer 136 may be adjusted by the composition ratio of at least one of Al and In.

The barrier layer 136 may be or include a semiconductor material having different characteristics from those of the channel layer 132. At least one of the polarization characteristics, energy band gap, and lattice constant of the barrier layer 136 may be different from that of the channel layer 132. For example, the barrier layer 136 may be or include a material having an energy band gap different from that of the channel layer 132. The barrier layer 136 may have an energy band gap higher than that of the channel layer 132, and may have electrical polarizability higher than that of the channel layer 132. By this barrier layer 136, the 2-dimensional electron gas 134 may be induced in the channel layer 132 having relatively low electrical polarizability. The barrier layer 136 may be referred to as a channel supply layer or a 2-dimensional electron gas supply layer. The 2-dimensional electron gas 134 may be formed in a portion of the channel layer 132 positioned below the interface between the channel layer 132 and the barrier layer 136. The 2-dimensional electron gas 134 may have relatively higher electron mobility.

The barrier layer 136 may be or include a single layer or multiple layers. When the barrier layer 136 includes multiple layers, the materials of the individual layers constituting the multiple layers may have different energy band gaps. The multiple layers constituting the barrier layer 136 may be disposed such that a layer closer to the channel layer 132 has a relatively higher energy band gap.

The gate electrode 155 may be positioned on the barrier layer 136. The gate electrode 155 may overlap a portion of the barrier layer 136. The gate electrode 155 may overlap a portion of the drift region DTR of the channel layer 132. The gate electrode 155 may be positioned between the source electrode 173 and the drain electrode 175. The gate electrode 155 may be spaced apart from the source electrode 173 and the drain electrode 175 in a first direction DR1. The first direction DR1 may be a direction parallel with the upper surface of the substrate 110 or the upper surface of the channel layer 132. The gate electrode 155 may be positioned midway between the source electrode 173 and the drain electrode 175. In other words, the separation distance between the gate electrode 155 and the source electrode 173 in the first direction DR1 may be similar to the separation distance between the gate electrode 155 and the drain electrode 175 in the first direction DR1. However, in some example embodiments, the gate electrode 155 may be offset from the midway position, and the gate electrode 155 may be positioned closer to one of the source electrode 173 or drain electrode 175. In some example embodiments, the gate electrode 155 may be positioned closer to the source electrode 173 than to the drain electrode 175. In other words, the separation distance between the gate electrode 155 and the source electrode 173 may be smaller than the separation distance between the gate electrode 155 and the drain electrode 175.

The gate electrode 155 may extend in a second direction DR2 different from the first direction DR1 on a plane. The second direction DR2 may be a direction parallel with the upper surface of the substrate 110 or the upper surface of the channel layer 132 and may be a direction intersecting the first direction DR1. For example, the second direction DR2 may be a direction perpendicular to the first direction DR1. The gate electrode 155 may have a rod shape extending along the second direction DR2.

The gate electrode 155 may be or include a conductive material. For example, the gate electrode 155 may be or include a metal, a metal alloy, a conductive metal nitride, a metal silicide, a doped semiconductor material, a conductive metal oxide, a conductive metal oxynitride, or the like. For example, the gate electrode 155 may be or include titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAIN), tantalum aluminum nitride (TaAIN), tungsten nitride (WN), ruthenium (Ru), titanium aluminum (TiAl), titanium aluminum carbo-nitride (TiAIC-N), titanium aluminum carbide (TiAIC), titanium carbide (TiC), tantalum carbo-nitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or a combination thereof, but is not limited thereto. The gate electrode 155 may include a single layer or multiple layers.

In some example embodiments, the semiconductor device may further include a hard mask layer that is positioned on the gate electrode 155. The hard mask layer may be a hard mask used to perform patterning on a gate electrode material layer or a gate semiconductor layer during formation of the gate electrode 155. However, the hard mask layer may be removed according to an etching condition during etching on the gate electrode material layer or according to a cleaning condition after the etching. As an example, the hard mask layer may be or include a silicon oxide, a silicon nitride, a silicon oxynitride, or a combination thereof.

The high electron mobility transistor H according to some example embodiments may further include a gate semiconductor layer 152 that is positioned between the barrier layer 136 and the gate electrode 155. The gate semiconductor layer 152 may be positioned on the barrier layer 136. The gate electrode 155 may be positioned on the gate semiconductor layer 152. The gate electrode 155 may be in contact with the gate semiconductor layer 152. The lower surface of the gate electrode 155 may be in contact with the gate semiconductor layer 152. However, example embodiments are not limited thereto, and one or more other desired layers may be further positioned or formed between the gate electrode 155 and the gate semiconductor layer 152. A Schottky contact may be formed or otherwise defined between the gate electrode 155 and the gate semiconductor layer 152. However, example embodiments are not limited thereto, and in some example embodiments, an ohmic contact may be formed or otherwise defined between the gate electrode 155 and the gate semiconductor layer 152. The gate semiconductor layer 152 may overlap the gate electrode 155 in a third direction DR3. The third direction DR3 may be a direction perpendicular to the first direction DR1 and the second direction DR2. In other words, the third direction DR3 may be a direction perpendicular to the upper surface of the substrate 110 or the upper surface of the channel layer 132. The gate electrode 155 may be patterned using the same mask as that for the gate semiconductor layer 152. Accordingly, the gate electrode 155 may have substantially the same planar shape as that of the gate semiconductor layer 152. The gate electrode 155 may have substantially the same width as that of the gate semiconductor layer 152.

The gate semiconductor layer 152 may be positioned between the source electrode 173 and the drain electrode 175. The gate semiconductor layer 152 may be spaced apart from the source electrode 173 and the drain electrode 175. The gate semiconductor layer 152 may be positioned approximately midway between the source electrode 173 and the drain electrode 175. In other words, the separation distance between the gate semiconductor layer 152 and the source electrode 173 in the first direction DR1 may be similar to the separation distance between the gate semiconductor layer 152 and the drain electrode 175 in the first direction DR1. However, the position of the gate semiconductor layer 152 is not limited thereto, and, in some example embodiments, the gate semiconductor layer 152 may be closer to one of the source electrode 173 or the drain electrode 175 than the other. In some example embodiments, the gate semiconductor layer 152 may be positioned closer to the source electrode 173 than to the drain electrode 175. In other words, the separation distance between the gate semiconductor layer 152 and the source electrode 173 may be smaller than the separation distance between the gate semiconductor layer 152 and the drain electrode 175.

The gate semiconductor layer 152 may be or include III-V materials, for example, one or more materials selected from nitrides containing at least one material of Al, Ga, In, and B. The gate semiconductor layer 152 may be formed of AlₓIn_{y}Ga_{1-x-y}N (wherein 0≤x≤1, 0≤y≤1, and x+y≤1). For example, the gate semiconductor layer 152 may be or include at least one of AlN, GaN, InN, InGaN, AlGaN, AlInN, and AlInGaN. The gate semiconductor layer 152 may be or include a material having an energy band gap different from that of the barrier layer 136. For example, the gate semiconductor layer 152 may be or include GaN, and the barrier layer 136 may be or include AlGaN. The gate semiconductor layer 152 may be doped with a predetermined impurity. In this case, the impurity with which the gate semiconductor layer 152 is doped may be a p-type impurity capable of providing holes. For example, the gate semiconductor layer 152 may be or include GaN doped with a p-type impurity. In other words, the gate semiconductor layer 152 may consist of a p-GaN layer. However, the gate semiconductor layer 152 is not limited thereto, and may be a p-AlGaN layer. For example, the impurity with which the gate semiconductor layer 152 is doped may be magnesium (Mg). The gate semiconductor layer 152 may consist of a single layer or multiple layers.

A depletion region DPR may be formed or defined in the channel layer 132 and adjacent the gate semiconductor layer 152. The depletion region DPR may be within (e.g., entirely within or partially overlapping) the drift region DTR, and may have a width smaller than that of the drift region DTR. As the gate semiconductor layer 152 having an energy band gap different from that of the barrier layer 136 is positioned on the barrier layer 136, the level of the energy band of a portion of the barrier layer 136 overlapping the gate semiconductor layer 152 may be increased. Accordingly, the depletion region DPR may be formed in the channel layer 132 overlapping the gate semiconductor layer 152. The depletion region DPR may be a region on the channel path of the channel layer 132 where the 2-dimensional electron gas 134 may not formed or which has an electron concentration lower than that of the other regions. In other words, the depletion region DPR may refer to a region in the drift region DTR where the flow of the 2-dimensional electron gas 134 is reduced or minimized. As the depletion region DPR is generated, a reduced current may flow between the source electrode 173 and the drain electrode 175, and the channel path may be restricted or limited. Accordingly, the high electron mobility transistor H according to some example embodiments may have a normally-off characteristic.

In other words, the high electron mobility transistor H according to some example embodiments may be a normally-off high electron mobility transistor (HEMT). In a normal state in which voltage is not applied to the gate electrode 155, the depletion region DPR may be formed or defined, and the high electron mobility transistor H according to some example embodiments may be reduced. When a voltage equal to or higher than a threshold voltage is applied to the gate electrode 155, the depletion region DPR may diminish, and the 2-dimensional electron gas 134 may be retained inside the drift region DTR. In other words, the 2-dimensional electron gas 134 may be formed over the entire channel path between the source electrode 173 and the drain electrode 175, and the high electron mobility transistor H according to some example embodiments may be turned on. In summary, the high electron mobility transistor H according to some example embodiments may include semiconductor layers having different electrical polarization characteristics, and a semiconductor layer having relatively high polarizability may cause the 2-dimensional electron gas 134 in another semiconductor layer forming a heterojunction with it. This 2-dimensional electron gas 134 may be used as a channel between the source electrode 173 and the drain electrode 175, and the continuation or interruption of the flow of the 2-dimensional electron gas 134 may be controlled by a bias voltage that is applied to the gate electrode 155. In the gate-off state, the flow of the 2-dimensional electron gas 134 may be reduced, whereby a reduced current may flow between the source electrode 173 and the drain electrode 175. In the gate-on state, as the flow of the 2-dimensional electron gas 134 is maintained, current may flow between the source electrode 173 and the drain electrode 175.

Although it has been described above that the high electron mobility transistor H according to some example embodiments is a normally-off high electron mobility transistor, example embodiments are not limited thereto. For example, the high electron mobility transistor H according to some example embodiments may be a normally-on high electron mobility transistor, in which case the gate semiconductor layer 152 may be omitted. Accordingly, the gate electrode 155 may be positioned directly on the barrier layer 136. In this structure, in a state where a reduced voltage is applied to the gate electrode 155, the 2-dimensional electron gas 134 may be used as a channel, and a flow of current may occur between the source electrode 173 and the drain electrode 175. Further, when a negative voltage is applied to the gate electrode 155, the depletion region DPR where the flow of the 2-dimensional electron gas 134 may dimmish may be formed under the gate electrode 155.

The seed layer 115, the buffer layer 120, the channel layer 132, the barrier layer 136, and the gate semiconductor layer 152 described above may be sequentially stacked on the substrate 110. In the high electron mobility transistor H according to some example embodiments, at least one of the seed layer 115, the buffer layer 120, the channel layer 132, the barrier layer 136, and the gate semiconductor layer 152 may be omitted. The seed layer 115, the buffer layer 120, the channel layer 132, the barrier layer 136, and the gate semiconductor layer 152 may be or include semiconductor materials including the same materials, and the material composition ratios of the individual layers may be different from one another considering the different functions the individual layers, the performance required for the high electron mobility transistor H, and the like.

The high electron mobility transistor H according to some example embodiments may further include a first protective layer 140 that is positioned or formed on the barrier layer 136, the gate semiconductor layer 152, and the gate electrode 155. The first protective layer 140 may cover or overlap the upper surface of the barrier layer 136, and may cover or overlap the side surfaces of the gate semiconductor layer 152, and may cover or overlap the upper surface and side surfaces of the gate electrode 155. The first protective layer 140 may be in contact with the barrier layer 136, the gate semiconductor layer 152, and/or the gate electrode 155. The barrier layer 136, the gate semiconductor layer 152, the gate electrode 155, and the like may be protected and be separated from the other components by the first protective layer 140. The first protective layer 140 may be or include an insulating material. For example, the first protective layer 140 may be or include an oxide such as SiO₂, Al₂O₃, etc. As another example, the first protective layer 140 may be or include a nitride such as SiN, or an oxynitride such as SiON. The first protective layer 140 may include a single layer or multiple layers.

The source electrode 173 and the drain electrode 175 may be positioned on the channel layer 132. The source electrode 173 and the drain electrode 175 may be spaced apart from each other, and the gate electrode 155 and the gate semiconductor layer 152 may be positioned between the source electrode 173 and the drain electrode 175. The gate electrode 155 and the gate semiconductor layer 152 are spaced apart from the source electrode 173 and the drain electrode 175. The source electrode 173 may be electrically connected to the channel layer 132 on one side of the gate electrode 155. The drain electrode 175 may be electrically connected to the channel layer 132 on the other side of the gate electrode 155. The source electrode 173 and the drain electrode 175 may be positioned on the outside of the drift region DTR of the channel layer 132. The interface between the source electrode 173 and the channel layer 132 may be one edge of the drift region DTR. Similarly, the interface between the drain electrode 175 and the channel layer 132 may be the other, opposite edge of the drift region DTR. However, example embodiments are not limited thereto, and the source electrode 173 and the drain electrode 175 may overlap the drift region DTR of the channel layer 132. In this case, the channel layer 132 may not be recessed, and the source electrode 173 and the drain electrode 175 may be positioned on the upper surface of the channel layer 132. Alternatively, the barrier layer 136 may not be penetrated, and some portions of the barrier layer 136 may be recessed, whereby the source electrode 173 and the drain electrode 175 may be positioned on the upper surface of the barrier layer 136. The lower surfaces of the source electrode 173 and the drain electrode 175 may be in contact with the upper surface of the barrier layer 136. The portions of the barrier layer 136 that are in contact with the source electrode 173 and the drain electrode 175 may have a relatively higher doping concentration. In this case, carriers passing through the 2-dimensional electron gas 134 may be transferred to the source electrode 173 and the drain electrode 175 through the portions of the barrier layer 136 doped at the high concentration, for example, the upper portions of the 2-dimensional electron gas 134. The source electrode 173 and the drain electrode 175 may not be in direct contact with the 2-dimensional electron gas 134 in a horizontal direction. The horizontal direction may refer to a direction parallel with the upper surface of the channel layer 132 or the barrier layer 136.

The source electrode 173 and the drain electrode 175 may be formed on the first protective layer 140. Trenches that are formed passing through the first protective layer 140, the barrier layer 136 and portions of the upper surface of the channel layer 132 may be formed on opposite sides of the gate electrode 155 and may be spaced apart from each other. Inside the trenches positioned on opposite sides of the gate electrode 155, the source electrode 173 and the drain electrode 175 may be formed, respectively. The source electrode 173 and the drain electrode 175 may be formed so as to fill the trenches. Inside the trenches, the source electrode 173 and the drain electrode 175 may be in contact with the channel layer 132 and the barrier layer 136. The channel layer 132 may form or define the bottom surfaces and side walls of the trenches, and the barrier layer 136 may form or define the side walls of the trenches. Therefore, the source electrode 173 and the drain electrode 175 may be in contact with the upper surface and side surface of the channel layer 132. Further, the source electrode 173 and the drain electrode 175 may be in contact with the side surface of the barrier layer 136. In other words, the source electrode 173 and the drain electrode 175 may cover the side surfaces of the channel layer 132 and the barrier layer 136. The upper surfaces of the source electrode 173 and the drain electrode 175 may protrude from the upper surface of the first protective layer 140. In some example embodiments, at least one of the source electrode 173 and the drain electrode 175 may cover at least a portion of the upper surface of the first protective layer 140.

The source electrode 173 and the drain electrode 175 may be spaced apart from each other in the first direction DR1. The source electrode 173 and the drain electrode 175 may extend in the second direction DR2 on a plane. The source electrode 173 and the drain electrode 175 may extend in a direction parallel with the gate electrode 155.

The source electrode 173 and the drain electrode 175 may be or include a conductive material. For example, the source electrode 173 and the drain electrode 175 may be or include a metal, a metal alloy, a conductive metal nitride, a metal silicide, a doped semiconductor material, a conductive metal oxide, a conductive metal oxynitride, or the like. For example, the source electrode 173 and the drain electrode 175 may be or include titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAIN), tantalum aluminum nitride (TaAIN), tungsten nitride (WN), ruthenium (Ru), titanium aluminum (TiAl), titanium aluminum carbo-nitride (TiAIC-N), titanium aluminum carbide (TiAIC), titanium carbide (TiC), tantalum carbo-nitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or a combination thereof, but is not limited thereto. The source electrode 173 and the drain electrode 175 may include a single layer or multiple layers. The source electrode 173 and the drain electrode 175 may form or define an ohmic contact with the channel layer 132. The regions in the channel layer 132 which are in contact with the source electrode 173 and the drain electrode 175 may be doped at a relatively higher concentration as compared to the other region.

A field dispersion layer 177 may be positioned between the source electrode 173 and the drain electrode 175. The field dispersion layer 177 may overlap the gate electrode 155 in the third direction DR3. The gate electrode 155 may be covered by the field dispersion layer 177. The field dispersion layer 177 may be electrically connected to the source electrode 173. The field dispersion layer 177 may be or include the same material as that of the source electrode 173, and may be positioned together with the source electrode 173 in the same layer. The field dispersion layer 177 may be formed together with the source electrode 173 in the same process. In other words, the boundary between the field dispersion layer 177 and the source electrode 173 may merge, and the field dispersion layer 177 may be formed integrally with the source electrode 173. However, the field dispersion layer 177 is not limited thereto, and may be an individual constituent element separated from the source electrode 173. Also, the field dispersion layer 177 and the source electrode 173 may be positioned on different layers, respectively, and may be formed using different processes, respectively. In some example embodiments, the field dispersion layer 177 may be electrically connected to the gate electrode 155. For example, an opening may be formed in the first protective layer 140 to overlap the gate electrode 155, and the field dispersion layer 177 may be connected to the gate electrode 155 through the opening. In some example embodiments, the field dispersion layer 177 may not be connected to the source electrode 173.

The field dispersion layer 177 may disperse an electric field concentrated around the gate electrode 155. When a high voltage is applied to the drain electrode 175 in the gate-off state, an electric field may be concentrated around the gate electrode 155. When the electric field is concentrated on the gate electrode 155, leakage current may increase, and the breakdown voltage may decrease. The electric field that is concentrated around the gate electrode 155 may be dispersed by the field dispersion layer 177, whereby leakage current may be reduced and the breakdown voltage may be increased.

Although FIG. 2 illustrates that the high electron mobility transistor H according to some example embodiments includes one pair of source electrode 173 and drain electrode 175, the numbers of source electrodes 173 and drain electrodes 175 are not limited thereto. For example, the source electrode 173 may include a plurality of source electrodes sequentially stacked in the third direction DR3 on the channel layer 132, and the drain electrode 175 may include a plurality of drain electrodes sequentially stacked in the third direction DR3 on the channel layer 132.

Although FIG. 2 illustrates that the high electron mobility transistor H according to some example embodiments includes a single field dispersion layer 177, example embodiments are not limited thereto. For example, the field dispersion layer 177 may include a plurality of field dispersion layers that overlap the gate electrode 155 in the third direction DR3. The plurality of field dispersion layers may be spaced apart from each other in the third direction DR3 by protective layers containing an insulating material. The plurality of field dispersion layers may be positioned between a plurality of pairs of source electrodes 173 and drain electrodes 175. The plurality of field dispersion layers may be electrically connected to the plurality of source electrodes, respectively. Each of the plurality of field dispersion layers may be formed integrally with a corresponding one of the plurality of source electrodes; however, example embodiments are not necessarily limited thereto. A first field dispersion layer of the plurality of field dispersion layers may entirely cover a second field dispersion layer positioned between the first field dispersion layer and a gate electrode 155. The width of the first field dispersion layer may be larger than the width of the second field dispersion layer. The width of the first field dispersion layer and the width of the second field dispersion layer may refer to the lengths along the first direction DR1 extending from a source electrode 173 to a drain electrode 175.

Referring to FIGS. 3 and 4, the first transistor T1 may include a first channel layer 132_1, a first barrier layer 136_1 that is positioned on the first channel layer 132_1, a first gate electrode 155_1 that is positioned on the first barrier layer 136_1, and a first source electrode 173_1 and a first drain electrode 175_1 that are positioned on opposite sides of the first gate electrode 155_1 on the first channel layer 132_1. The first transistor T1 may further include a first gate semiconductor layer 152_1 that is positioned between the first barrier layer 136_1 and the first gate electrode 155_1. Between the first source electrode 173_1 and the first drain electrode 175_1, a first field dispersion layer 177_1 may be positioned.

The second transistor T2 may include a second channel layer 132_2, a second barrier layer 136_2 that is positioned on the second channel layer 132_2, a second gate electrode 155_2 that is positioned on the second barrier layer 136_2, and a second source electrode 173_2 and a second drain electrode 175_2 that are positioned on opposite sides of the second gate electrode 155_2 on the second channel layer 132_2. The second transistor T2 may further include a second gate semiconductor layer 152_2 that is positioned between the second barrier layer 136_2 and the second gate electrode 155_2. Between the second source electrode 173_2 and the second drain electrode 175_2, a second field dispersion layer 177_2 may be positioned.

Each of the first transistor T1 and the second transistor T2 may be a high electron mobility transistor (HEMT). The elements of the first transistor T1 and the elements of the second transistor T2 may correspond to the elements of the high electron mobility transistor H described above with reference to FIG. 2. The elements of the first transistor T1 and the second transistor T2 may be formed simultaneously in the same process of the high electron mobility transistor H.

The first channel layer 132_1 and the second channel layer 132_2 may correspond to the channel layer 132. In other words, the first channel layer 132_1 and the second channel layer 132_2 may be formed together with the channel layer 132 in the same process, and may be or include the same material. The first barrier layer 136_1 and the second barrier layer 136_2 may correspond to the barrier layer 136. In other words, the first barrier layer 136_1 and the second barrier layer 136_2 may be formed together with the barrier layer 136 in the same process, and may be or include the same material. The first gate electrode 155_1 and the second gate electrode 155_2 may correspond to the gate electrode 155. In other words, the first gate electrode 155_1 and the second gate electrode 155_2 may be formed together with the gate electrode 155 in the same process, and may be or include the same material. The first gate semiconductor layer 152_1 and the second gate semiconductor layer 152_2 may correspond to the gate semiconductor layer 152. In other words, the first gate semiconductor layer 152_1 and the second gate semiconductor layer 152_2 may be formed together with the gate semiconductor layer 152 in the same process, and may be or include the same material.

The first source electrode 173_1 and the second source electrode 173_2 may correspond to the source electrode 173. The first drain electrode 175_1 and the second drain electrode 175_2 may correspond to the drain electrode 175. The first field dispersion layer 177_1 and the second field dispersion layer 177_2 may correspond to the field dispersion layer 177. The first source electrode 173_1 and the first drain electrode 175_1 may be formed together with the second source electrode 173_2 and the second drain electrode 175_2 in the same process, and may be or include the same material. The first source electrode 173_1 and the first drain electrode 175_1 may be formed together with the source electrode 173 and the drain electrode 175 in the same process, and may be or include the same material. The second source electrode 173_2 and the second drain electrode 175_2 may be formed together with the source electrode 173 and the drain electrode 175 in the same process, and may be or include the same material.

The first channel layer 132_1 may include a first drift region DTR1 which overlaps the first barrier layer 136_1 between the first source electrode 173_1 and the first drain electrode 175_1. The first drift region DTR1 may include a first depletion region DPR1 which overlaps the first gate semiconductor layer 152_1. Within the first channel layer 132_1, a 2-dimensional electron gas 134_1 of a first channel may be positioned. When the first transistor T1 is in the ON state, since the flow of the 2-dimensional electron gas 134_1 of the first channel continues inside the first drift region DTR1, current may flow between the first source electrode 173_1 and the first drain electrode 175_1. When the first transistor T1 is in the OFF state, since the flow of the 2-dimensional electron gas 134_1 of the first channel is interrupted inside the first depletion region DPR1, current flow may be reduced between the first source electrode 173_1 and the first drain electrode 175_1.

The second channel layer 132_2 may include a second drift region DTR2 which overlaps the second barrier layer 136_2 between the second source electrode 173_2 and the second drain electrode 175_2. The second drift region DTR2 may include a second depletion region DPR2 which overlaps the second gate semiconductor layer 152_2. Inside the second channel layer 132_2, a 2-dimensional electron gas 134_2 of a second channel may be positioned. When the second transistor T2 is in the ON state, since the flow of the 2-dimensional electron gas 134_2 of the second channel is maintained in the second drift region DTR2, current may flow between the second source electrode 173_2 and the second drain electrode 175_2. When the second transistor T2 is in the OFF state, since the flow of the 2-dimensional electron gas 134_2 of the second channel is interrupted inside the second depletion region DPR2, current flow may be reduced between the second source electrode 173_2 and the second drain electrode 175_2.

The first drift region DTR1 and the second drift region DTR2 may correspond to the drift region DTR, and the first depletion region DPR1 and the second depletion region DPR2 may correspond to the depletion region DPR. The 2-dimensional electron gas 134_1 of the first channel and the 2-dimensional electron gas 134_2 of the second channel may correspond to the 2-dimensional electron gas 134.

The first transistor T1 and the second transistor T2 may be the same as or similar to the high electron mobility transistor H in FIG. 2, and may be best understood with reference thereto, and a repeat description thereof is omitted for the sake of brevity. The constituent elements of the first transistor T1 and the second transistor T2, and the constituent elements of the high electron mobility transistor H corresponding thereto may be positioned in the same layer. For example, the constituent elements of the first transistor T1 and the second transistor T2, and the constituent elements of the high electron mobility transistor H corresponding thereto may be formed simultaneously in the same process; however, example embodiments are not necessarily limited thereto.

Referring to FIG. 1, as described above, the first transistor T1 is connected to the first power voltage VDD, and the second transistor T2 is connected to the second power voltage VSS different from the first power voltage VDD. The second power voltage VSS may be a voltage lower than the first power voltage VDD, and may be connected to the ground. Further, the first transistor T1 and the second transistor T2 may be connected in series with each other. Specifically, the first drain electrode 175_1 of the first transistor T1 is connected to the first power voltage, and the second source electrode 173_2 of the second transistor T2 is connected to the second power voltage. The first power voltage may be higher than the second power voltage. The first source electrode 173_1 of the first transistor T1 and the second drain electrode 175_2 of the second transistor T2 are connected to each other.

Although it is shown in FIGS. 3 and 4 that the first source electrode 173_1 and the second drain electrode 175_2 are integrally formed, example embodiments are not limited thereto. The first source electrode 173_1 and the second drain electrode 175_2 may be separate individual components, in which case the first source electrode 173_1 and the second drain electrode 175_2 may be connected by another constituent element.

The first transistor T1 and the second transistor T2 are positioned on the substrate 110. The substrate 110 may be a silicon substrate. The substrate 110 may be a silicon substrate of a first conductivity type doped with a first conductivity type impurity.

Between at least one of the first transistor T1 and the second transistor T2 and the first conductivity type substrate 110, a well region 112 of a second conductivity type is positioned. The well region 112 may be or include silicon. The well region 112 may be or include silicon doped with an impurity of the second conductivity type different from the first conductivity type.

In some example embodiments, the well region 112 may be positioned between the first transistor T1 and the substrate 110. In some example embodiments, the first conductivity type may be a p-type, and the second conductivity type may be an n-type. In other words, between a p-type substrate 110 and a first gate electrode 155_1, an n-type well region 112 may be positioned.

Referring to FIG. 4, the first channel layer 132_1 and the second channel layer 132_2 may be positioned on the substrate 110. The first barrier layer 136_1 may be positioned on the first channel layer 132_1, and the second barrier layer 136_2 may be positioned on the second channel layer 132_2. The first barrier layer 136_1 may be positioned between the first source electrode 173_1 and the first drain electrode 175_1. The second barrier layer 136_2 may be positioned between the second source electrode 173_2 and the second drain electrode 175_2. The first gate electrode 155_1 may be positioned on the first barrier layer 136_1, and the first gate semiconductor layer 152_1 may be positioned between the first barrier layer 136_1 and the first gate electrode 155_1. The second gate electrode 155_2 may be positioned on the second barrier layer 136_2, and the second gate semiconductor layer 152_2 may be positioned between the second barrier layer 136_2 and the second gate electrode 155_2.

Between the first gate electrode 155_1 and the substrate 110, the first gate semiconductor layer 152_1, the first barrier layer 136_1, the first channel layer 132_1, the buffer layer 120, the seed layer 115, and the well region 112 may be positioned. Between the second gate electrode 155_2 and the substrate 110, the second gate semiconductor layer 152_2, the second barrier layer 136_2, the second channel layer 132_2, the buffer layer 120, and the seed layer 115 may be positioned. In other words, the well region 112 may be further positioned between the first gate electrode 155_1 and the substrate 110.

The well region 112 may be positioned on the upper surface of the substrate 110. As described above, the substrate 110 may be the p-type, and the well region 112 may be the n-type. Since the upper surface of the substrate 110 and the lower surface of the well region 112, a p-n junction structure may be formed at the interface of the substrate 110 and the well region 112. In the p-n junction structure, when a reverse bias is applied, a reduced current may flow between the well region 112 and the substrate 110.

The well region 112 may be formed through an epitaxial growth process. For example, the well region 112 may be formed by forming a silicon layer containing the n-type impurity on the entire upper surface of the p-type substrate 110 through an epitaxial process and then performing patterning on the silicon layer. Accordingly, the well region 112 may cover a portion of the upper surface of the substrate 110, and may not cover the other portion.

The seed layer 115 may be positioned on the substrate 110 and the well region 112. The seed layer 115 may cover the upper surface of the substrate 110. The seed layer 115 may cover the side surface and upper surface of the well region 112. The lower surface of the seed layer 115 may be in contact with the upper surface of the substrate 110, the side surface of the well region 112, and the upper surface of the well region 112.

In some example embodiments, the seed layer 115 may have a step profile due to the well region 112. The portion of the seed layer 115 which is positioned on the well region 112 may be positioned at a level higher than that of the portion of the seed layer 115 which is positioned directly on the substrate 110.

The buffer layer 120 may be positioned on the seed layer 115. The buffer layer 120 may entirely cover the seed layer 115. The thickness of the buffer layer 120 in the third direction DR3 may be larger than the thickness of the seed layer 115 in the third direction DR3.

In some example embodiments, the lower surface of the buffer layer 120 may have a step feature along the profile of the upper surface of the seed layer 115, but the upper surface of the buffer layer 120 may be relatively flat or planar.

The first channel layer 132_1 and the second channel layer 132_2 may be positioned on the buffer layer 120. The first source electrode 173_1 and the first drain electrode 175_1 may be positioned on the first channel layer 132_1, and the second source electrode 173_2 and the second drain electrode 175_2 may be positioned on the second channel layer 132_2. The first source electrode 173_1 and the first drain electrode 175_1 may be spaced apart from each other in the first direction DR1, and the first gate electrode 155_1 may be positioned between the first source electrode 173_1 and the first drain electrode 175_1. The first gate electrode 155_1 may be closer to the first source electrode 173_1 than the first drain electrode 175_1. The second source electrode 173_2 and the second drain electrode 175_2 may be spaced apart from each other in the second direction DR1, and the second gate electrode 155_2 may be positioned between the second source electrode 173_2 and the second drain electrode 175_2. The second gate electrode 155_2 may be closer to the second source electrode 173_2 than the second drain electrode 175_2.

In some example embodiments of FIGS. 3 and 4, the first source electrode 173_1 and the second drain electrode 175_2 may be integrally formed, and accordingly, the first source electrode 173_1 and the second drain electrode 175_2 may be referred to as the common electrode CE of the first transistor T1 and the second transistor T2. On a plane, the second source electrode 173_2, the second gate electrode 155_2, the common electrode CE, the first gate electrode 155_1, the first drain electrode 175_1 may be sequentially positioned in the first direction DR1. The first channel layer 132_1 and the second channel layer 132_2 may be spaced apart from each other in the first direction DR1 by the common electrode CE.

According to some example embodiments, the common electrode CE, the first gate electrode 155_1, and the first drain electrode 175_1 may be positioned on the well region 112. The second source electrode 173_2 and the second gate electrode 155_2 may be positioned offset from the well region 112. The common electrode CE, the first gate electrode 155_1, and the first drain electrode 175_1 may overlap the well region 112 in the third direction DR3. A portion of the common electrode CE may overlap the well region 112 in the third direction DR3, and the other portion may not overlap the well region 112 in the third direction DR3. The second source electrode 173_2 and the second gate electrode 155_2 may not overlap the well region 112 in the third direction DR3. The well region 112 may overlap the first drift region DTR1 of the first channel layer 132_1 in the third direction DR3. The well region 112 may not overlap the second drift region DTR2 of the second channel layer 132_2 in the third direction DR3.

The first source electrode 173_1 may include a first contact portion 173_10. The first contact portion 173_10 may be in contact with the well region 112. The first contact portion 173_10 may extend from the interface of the first source electrode 173_1 and the first channel layer 132_1 so as to pass through the first channel layer 132_1, the buffer layer 120, and the seed layer 115 in the third direction DR3 and be connected to the well region 112. The first source electrode 173_1 may be connected to the well region 112 by the first contact portion 173_10. In FIG. 4, the lower surface of the first contact portion 173_10 may be positioned between the upper surface and lower surface of the well region 112; however, example embodiments are not limited thereto. In some example embodiments, the lower surface of the first contact portion 173_10 may be positioned substantially at the same level as that of the upper surface or lower surface of the well region 112.

The second source electrode 173_2 may include a second contact portion 173_20. The second contact portion 173_20 may be in contact with the substrate 110. The second contact portion 173_20 may extend from the interface of the second source electrode 173_2 and the second channel layer 132_2 so as to pass through the second channel layer 132_2, the buffer layer 120, and the seed layer 115 in the third direction DR3 and be connected to the substrate 110. The second source electrode 173_2 may be connected to the substrate 110 by the second contact portion 173_20. In FIG. 4, the lower surface of the second contact portion 173_20 may be at a level lower than that of the upper surface of the substrate 110; however, example embodiments are not limited thereto. For example, the lower surface of the second contact portion 173_20 may be substantially at the same level as that of the upper surface of the substrate 110.

According to some example embodiments, the first contact portion 173_10 of the first source electrode 173_1 may be in contact with the n-type well region 112, and the second contact portion 173_20 of the second source electrode 173_2 may be in contact with the p-type substrate 110. The first contact portion 173_10 of the first source electrode 173_1 and the second contact portion 173_20 of the second source electrode 173_2 may be in contact with layers of different conductivity types, respectively.

According to some example embodiments, the second contact portion 173_20 of the second source electrode 173_2 may be in contact with the substrate 110, and the first contact portion 173_10 of the first source electrode 173_1 may be in contact with the well region 112 positioned on the substrate 110. The upper surface of the substrate 110 may be positioned at a level lower than that of the upper surface of the well region 112. For example, the upper surface of the substrate 110 may be substantially at the same level as that of the lower surface of the well region 112. According to some example embodiments, the lower surface of the second contact portion 173_20 may be at a level lower than that of the lower surface of the first contact portion 173_10. The height h2 of the second contact portion 173_20 in the third direction DR3 may be larger than the height h1 of the first contact portion 173_10 in the third direction DR3. The height h2 of the second contact portion 173_20 in the third direction DR3 may be defined as the distance from the interface where the second source electrode 173_2 is in contact with the second channel layer 132_2 to the interface where the second contact portion 173_20 is in contact with the substrate 110. The height h1 of the first contact portion 173_10 in the third direction DR3 may be defined as the distance from the interface where the first source electrode 173_1 is in contact with the first channel layer 132_1 to the interface where the first contact portion 173_10 is in contact with the well region 112.

The well region 112 may include a first well region 112a and a second well region 112b. The first well region 112a may be a portion of the well region 112 which is positioned between the first gate electrode 155_1 and the substrate 110. The first well region 112a may be a portion of the well region 112 which overlaps the first drift region DTR1 of the first channel layer 132_1 in the third direction DR3. The second well region 112b may be spaced apart from the first well region 112a by a first insulating pattern IP1.

The first insulating pattern IP1 may be formed integrally with the first protective layer 140 in the same process. For example, the first insulating pattern IP1 may be formed by forming a trench so as to pass through the first barrier layer 136_1, the first channel layer 132_1, the buffer layer 120, the seed layer 115, and the well region 112 and filling the trench with an insulating material. The first insulating pattern IP1 may be or include the same insulating material as that of the first protective layer 140. For example, the first insulating pattern IP1 may be or include an oxide such as SiO₂ or Al₂O₃. As an example, the first insulating pattern IP1 may be or include a nitride such as SiN, or an oxynitride such as SiON. The first insulating pattern IP1 may include a single layer or multiple layers.

The lower surface of the first insulating pattern IP1 may be in contact with the substrate 110. In other words, the first insulating pattern IP1 may completely pass through the well region 112 in the third direction DR3. Although it is shown in FIG. 4 that the width of the first insulating pattern IP1 in the first direction DR1 is relatively constant, example embodiments are not limited thereto. The width of the first insulating pattern IP1 in the first direction DR1 may decrease as it extends toward the lower surface. In other words, although it is shown in FIG. 4 that the cross-sectional shapes of the first insulating pattern IP1 in the first direction DR1 and the third direction DR3 are rectangular, example embodiments are not limited thereto. As described above, the cross-sectional shapes of the first insulating pattern IP1 in the first direction DR1 and the third direction DR3 may be trapezoidal.

On both sides of the first insulating pattern IP1, portions of the first drain electrode 175_1 may be positioned. The first drain electrode 175_1 may be curved so as to surround the upper surface and both side surfaces of the first insulating pattern IP1 and be connected to the second well region 112b. The first drain electrode 175_1 may include a third contact portion 175_10. The third contact portion 175_10 may be in contact with the second well region 112b. The third contact portion 175_10 may pass through the first protective layer 140, the first barrier layer 136_1, the first channel layer 132_1, the buffer layer 120, and the seed layer 115, and be connected to the second well region 112b. The first drain electrode 175_1 may be connected to the second well region 112b by the third contact portion 175_10. In FIG. 4, the lower surface of the third contact portion 175_10 may be positioned at a level between the upper surface and lower surface of the second well region 112b; however, example embodiments are not limited thereto. For example, the lower surface of the third contact portion 175_10 may be positioned substantially at the same level as that of the upper surface or lower surface of the second well region 112b. The first insulating pattern IP1 may be positioned between the portion of the first drain electrode 175_1 defining the first drift region DTR1 and the third contact portion 175_10 of the first drain electrode 175_1.

According to some example embodiments, the first contact portion 173_10 of the first source electrode 173_1 may be in contact with the first well region 112a, and the third contact portion 175_10 of the first drain electrode 175_1 may be in contact with the second well region 112b. The first well region 112a and the second well region 112b may be the same n-type. The first contact portion 173_10 of the first source electrode 173_1 and the third contact portion 175_10 of the first drain electrode 175_1 may be in contact with layers of the same conductivity type spaced apart from each other, respectively.

Although it is shown in FIG. 3 that the first contact portion 173_10, the second contact portion 173_20, and the third contact portion 175_10 extend along the second direction DR2, example embodiments are not necessarily limited thereto. The widths of the first contact portion 173_10, the second contact portion 173_20, and the third contact portion 175_10 in the second direction DR2 may be changed depending on application and/or design. Also, FIG. 3 illustrates single first contact portions 173_10, second contact portions 173_20, and third contact portions 175_10, example embodiments are not limited thereto. For example, a plurality of first contact portions, a plurality of second contact portions 173_20, and/or a plurality of third contact portions 175_10 may be arranged at predetermined intervals along the second direction DR2.

Also, although it is shown in FIG. 3 that the planar shapes of the first contact portion 173_10, the second contact portion 173_20, and the third contact portion 175_10 are rectangular, example embodiments are not limited thereto. For example, the first contact portion 173_10, the second contact portion 173_20, and the third contact portion 175_10 may be shaped as circles, ellipses, or polygons other than rectangles.

Although it is shown in FIG. 4 that the widths of the first contact portion 173_10, the second contact portion 173_20, and the third contact portion 175_10 in the first direction DR1 are the same, example embodiments are not limited thereto. The first contact portion 173_10, the second contact portion 173_20, and the third contact portion 175_10 may have a shape whose width in the first direction DR1 decreases as it goes toward the lower surface. In other words, although it is shown in FIG. 4 that the cross-sectional shapes of the first contact portion 173_10, the second contact portion 173_20, and the third contact portion 175_10 in the first direction DR1 and the third direction DR3 are rectangular, example embodiments are not limited thereto. As described above, the cross-sectional shapes of the first contact portion 173_10, the second contact portion 173_20, and the third contact portion 175_10 in the first direction DR1 and the third direction DR3 may be trapezoidal.

According to some example embodiments, the first transistor T1 and the second transistor T2 may be positioned on the substrate 110, and the well region 112 having the conductivity type different from that of the substrate 110 may be positioned between the substrate 110 and the first transistor T1. Since the first transistor T1 and the second transistor T2 have the different conductivity types on one substrate 110, they may be positioned in two regions insulated from each other, respectively. According to some example embodiments, a silicon substrate or a silicon-on-insulator (SOI) substrates may be used to form two high electron mobility transistors together between the first power voltage and the second power voltage lower than the first power voltage on one substrate such that the high electron mobility transistors are connected in series with each other.

According to some example embodiments, the first contact portion 173_10 of the first source electrode 173_1 may be in contact with the well region 112, and the second contact portion 173_20 of the second source electrode 173_2 may be in contact with the substrate 110. The well region 112 may correspond to the substrate (or body) of the first transistor T1, and the substrate 110 may correspond to the substrate (or body) of the second transistor T2. According to some example embodiments, by connecting the source electrode of each of the first transistor T1 and the second transistor T2 to the substrate of the corresponding transistor, it is possible to reduce or minimize a body effect phenomenon.

According to some example embodiments, the third contact portion 175_10 of the first drain electrode 175_1 may be in contact with the second well region 112b. To the first drain electrode 175_1 which is connected to the first power voltage, a high voltage may be applied. Accordingly, an avalanche breakdown phenomenon may occur in that reverse current may flow between the substrate 110 and the first well region 112a where the first transistor T1 is positioned. According to some example embodiments, by connecting the first drain electrode 175_1 of the first transistor T1, to which a high voltage is applied, to the second well region 112b separate from the first well region 112a connected to the first source electrode 173_1 while having a p-n junction structure, it is possible to reduce or minimize an avalanche breakdown phenomenon.

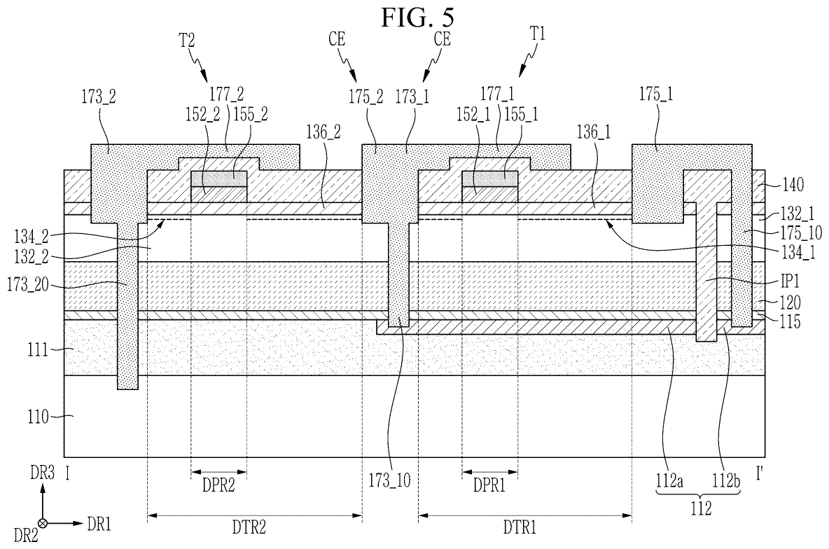

Hereinafter, a semiconductor device that is similar in some respects to semiconductor device of FIGS. 1 to 4 will be described with reference to FIG. 5.

FIG. 5 is a cross-sectional view illustrating an amplifier circuit of a semiconductor device according to some example embodiments. FIG. 5 may be a cross-sectional view taken along line I-I′ of FIG. 3. The semiconductor device in FIG. 5 may be same as or similar in some respects to the semiconductor device of FIGS. 1-4, and therefore may be best understood with reference thereto where like numerals indicate like elements not described again in detail.

In some example embodiments of FIG. 5, the well region 112 may be positioned between the first transistor T1 and the substrate 110. The substrate 110 may be the first conductivity type, and the well region 112 may be the second conductivity type. In some example embodiments, the first conductivity type may be a p-type, and the second conductivity type may be an n-type. In other words, the n-type well region 112 may be positioned between the p-type substrate 110 and the first transistor T1.

In some example embodiments of FIG. 5, an epitaxial layer 111 may be positioned on the substrate 110. The epitaxial layer 111 may be positioned between the substrate 110 and the first transistor T1 and between the substrate 110 and the second transistor T2. The epitaxial layer 111 may be or include silicon. According to some example embodiments, the epitaxial layer 111 may be the same first conductivity type as that of the substrate 110. In some example embodiments, the epitaxial layer 111 may be formed by forming a silicon layer containing a p-type impurity on the entire upper surface of the substrate 110 through an epitaxial process.

According to some example embodiments, the epitaxial layer 111 may have a lower concentration of impurities of the first conductivity type than the substrate 110. In other words, the substrate 110 may be a p⁺ Si layer, and the epitaxial layer 111 may be a p⁻ Si layer.

Referring to FIG. 5, the epitaxial layer 111 may be positioned on the substrate 110. According to some example embodiments, the well region 112 may be a portion of the epitaxial layer 111. In some example embodiments, a photoresist layer may be deposited on the epitaxial layer 111, and a photoresist pattern may be formed through exposure and development processes. The well region 112 may be formed by doping the upper surface of the epitaxial layer 111, which is exposed and not covered by the photoresist pattern, with an n-type impurity through an implantation process.

According to some example embodiments, the epitaxial layer 111 may include a portion of the first conductivity type and a portion of the second conductivity type, and the portion of the second conductivity type may correspond to the well region 112. The upper surface of the well region 112 may be positioned substantially at the same level as that of the upper surface of the first conductivity type portion of the epitaxial layer 111. The well region 112 may have a structure buried in the epitaxial layer 111. The side surface and lower surface of the well region 112 may be surrounded by the first conductivity type portion of the epitaxial layer 111.

The seed layer 115 may be positioned on the epitaxial layer 111. The seed layer 115 may cover the upper surface of the first conductivity type portion of the epitaxial layer 111 and the upper surface of the well region 112. The lower surface of the seed layer 115 may be in contact with the upper surface of the first conductivity type portion and the upper surface of the well region 112.

In some example embodiments, the seed layer 115 may be relatively flat or planar. Since the upper surface of the well region 112 and the upper surface of the first conductivity type portion of the epitaxial layer 111 are positioned substantially at the same level, the seed layer 115 may be relatively flat or planar. The portion of the seed layer 115 that is positioned on the first conductivity type portion of the epitaxial layer 111 and the portion of the seed layer 115 that is positioned on the well region 112 may be positioned substantially at the same level.

The buffer layer 120 may be positioned on the seed layer 115. In some example embodiments, the lower surface of the buffer layer 120 may be relatively flat or planar along the profile of the upper surface of the seed layer 115.

In some example embodiments of FIG. 5, the second contact portion 173_20 of the second source electrode 173_2 may pass through the epitaxial layer 111 and be connected to the substrate 110. In some example embodiments, the second contact portion 173_20 may extend from the interface of the second source electrode 173_2 and the second channel layer 132_2, pass through the second channel layer 132_2, the buffer layer 120, the seed layer 115, and the epitaxial layer 111 in the third direction DR3, and be connected to the substrate 110. In some example embodiments of FIG. 5, the second contact portion 173_20 may further pass through the epitaxial layer 111.

The first well region 112a and the second well region 112b may be spaced apart or separated from each other by the first insulating pattern IP1. The first insulating pattern IP1 may completely pass through the well region 112 in the third direction DR3. In some example embodiments of FIG. 5, the lower surface of the first insulating pattern IP1 may be in contact with the epitaxial layer 111; however, example embodiments are not limited thereto. In some example embodiments, the first insulating pattern IP1 may completely pass through the epitaxial layer 111 in the third direction DR3 such that the lower surface of the first insulating pattern IP1 is in contact with the substrate 110.

The semiconductor device in FIG. 5 may be the same as or similar to the semiconductor device in FIG. 4 and may be best understood with reference thereto, where like numerals indicate like elements not described again in detail.

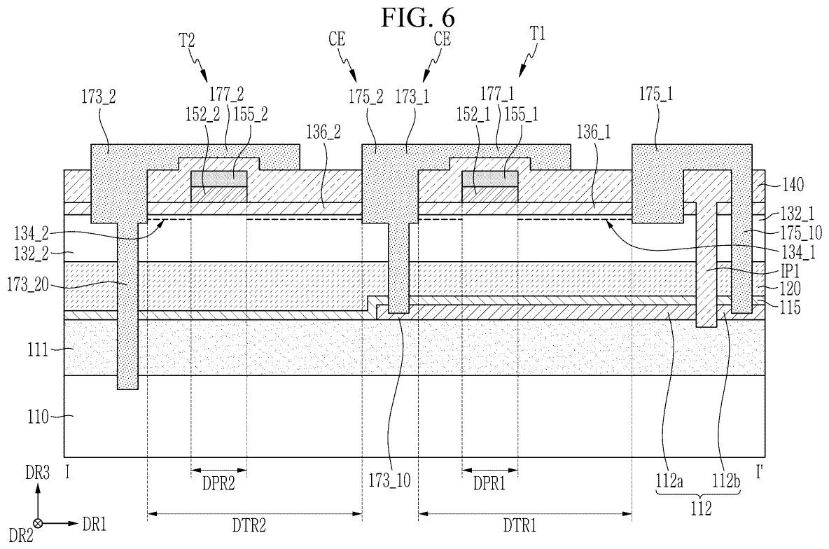

The semiconductor device in FIG. 6 may be the same as or similar to the semiconductor device in FIG. 5 and may be best understood with reference thereto, where like numerals indicate like elements not described again in detail.

FIG. 6 is a cross-sectional view illustrating an amplifier circuit of a semiconductor device according to some example embodiments. FIG. 6 is a cross-sectional view taken along line I-I′ of FIG. 3.

In some example embodiments of FIG. 6, an epitaxial layer 111 may be positioned on the substrate 110. The epitaxial layer 111 may be positioned between the substrate 110 and the first transistor T1 and between the substrate 110 and the second transistor T2. According to some example embodiments, the epitaxial layer 111 may be the same first conductivity type as that of the substrate 110, and may have a lower concentration of impurities of the first conductivity type than the substrate 110. In other words, the substrate 110 may be a p⁺ Si layer, and the epitaxial layer 111 may be a p⁻ Si layer.

According to some example embodiments, the well region 112 may be formed in a portion of the epitaxial layer 111. According to some example embodiments, the well region 112 may be positioned between the first transistor T1 and the substrate 110.

In some example embodiments, the entire upper surface of the epitaxial layer 111 may be doped with an n-type impurity by performing an implantation process. Subsequently, a photoresist layer may be deposited on the upper surface of the epitaxial layer 111, and a photoresist pattern may be formed through exposure and development processes. Next, a partial region of the epitaxial layer 111 may be etched using the photoresist pattern as an etch mask, whereby the well region 112 may be formed.

According to some example embodiments, the epitaxial layer 111 may include a portion of the first conductivity type and a portion of the second conductivity type, and the portion of the second conductivity type may correspond to the well region 112. The well region 112 may correspond to the region which has not been etched in the above-mentioned etching process. In some example embodiments of FIG. 6, the upper surface of the well region 112 may be at a higher level than the upper surface of the first conductivity type portion of the epitaxial layer 111. The well region 112 may have a structure protruding from the first conductivity type portion of the epitaxial layer 111.

The seed layer 115 may be positioned on the epitaxial layer 111. The seed layer 115 may cover the upper surface of the first conductivity type portion of the epitaxial layer 111 and the upper surface of the well region 112. In some example embodiments of FIG. 6, the seed layer 115 may further cover the side surface of the well region 112. The lower surface of the seed layer 115 may be in contact with the upper surface of the first conductivity type portion of the epitaxial layer 111, the side surface of the well region 112, and the upper surface of the well region 112.

In some example embodiments, the seed layer 115 may have a step profile due to the well region 112. The portion of the seed layer 115 that is positioned on the well region 112 may be at a higher level than the portion of the seed layer 115 that is on the first conductivity type portion of the epitaxial layer 111.

The buffer layer 120 may be positioned on the seed layer 115. In some example embodiments, the lower surface of the buffer layer 120 may have a step feature along the profile of the upper surface of the seed layer 115, but the upper surface of the buffer layer 120 may be relatively flat or planar.

A description of elements in FIG. 6 that are same as or similar to elements in FIG. 5, a detailed description thereof may be omitted herein for the sake of brevity.

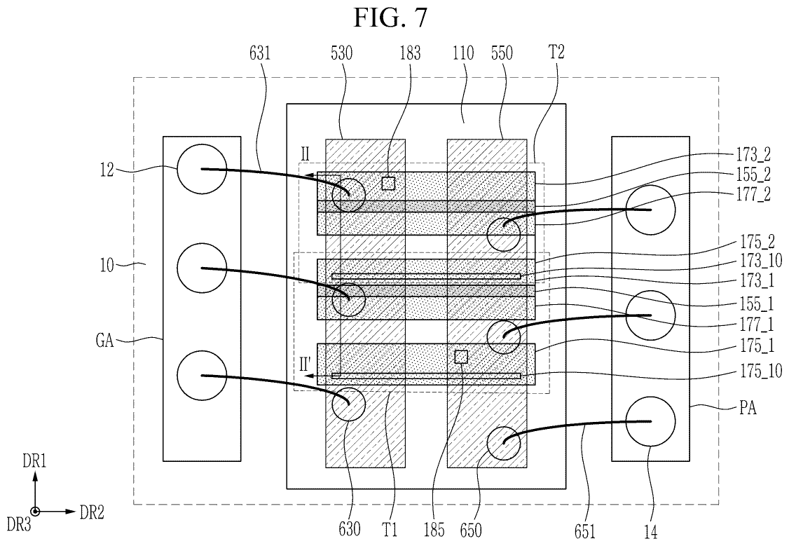

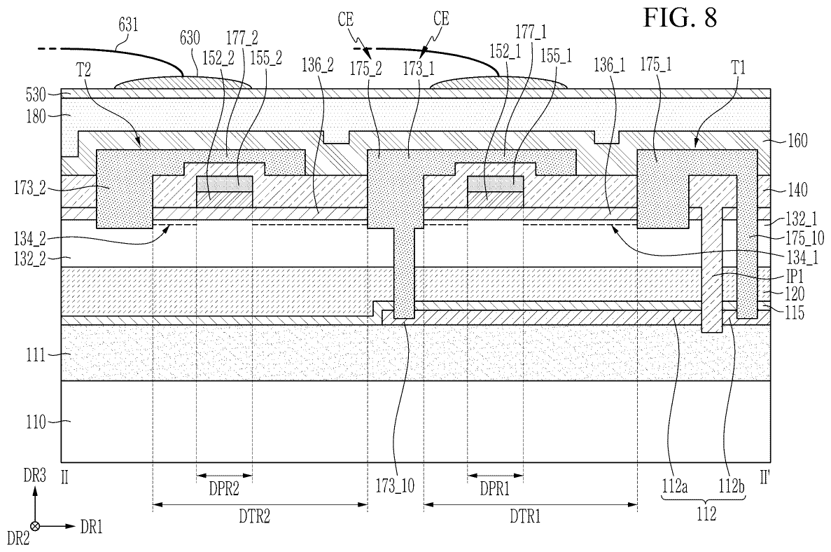

The semiconductor device in FIGS. 7 and 8 may be the same as or similar to the semiconductor device in FIG. 6 and may be best understood with reference thereto, where like numerals indicate like elements not described again in detail.

FIG. 7 is a plan view illustrating a semiconductor device according to some example embodiments. FIG. 8 is a cross-sectional view taken along line II-II′ of FIG. 7. In some example embodiments of the semiconductor device of FIGS. 7 and 8, the second contact portion 173_20 may be omitted.

Referring to FIGS. 7 and 8, a semiconductor device according to some example embodiments may further include a package substrate 10. The substrate 110 may be positioned on the package substrate 10. The package substrate 10 may include insulating layers containing ceramic or plastic, and a conductive pattern that is interposed between the insulating layers. The package substrate 10 may be, for example, a printed circuit board (PCB).

The semiconductor device according to some example embodiments may further include a second protective layer 160 and an interlayer insulating layer 180 which are positioned on the first drain electrode 175_1, the first source electrode 173_1, the second drain electrode 175_2, and the second source electrode 173_2. The second protective layer 160 may be in contact with the first drain electrode 175_1, the first source electrode 173_1, the second drain electrode 175_2, and the second source electrode 173_2. The second protective layer 160 may be in contact with the first protective layer 140. The second protective layer 160 may be spaced apart from the first barrier layer 136_1, the second barrier layer 136_2, the first gate electrode 155_1, the second gate electrode 155_2, the first gate semiconductor layer 152_1, and the second gate semiconductor layer 152_2 by the first protective layer 140.

The second protective layer 160 may be or include an insulating material. For example, the second protective layer 160 may be or include an oxide such as SiO₂, Al₂O₃, etc. In some example embodiments, the second protective layer 160 may be or include a nitride such as SiN, or an oxynitride such as SiON. The second protective layer 160 may be or include the same material as that of the first protective layer 140, or may be or include a material different from that of the first protective layer 140. When the first protective layer 140 and the second protective layer 160 include the same material, the boundary between the first protective layer 140 and the second protective layer 160 may merge. The second protective layer 160 may be or include a single layer or multiple layers.

The interlayer insulating layer 180 may be positioned on the first drain electrode 175_1, the first source electrode 173_1, the second drain electrode 175_2, and the second source electrode 173_2. The interlayer insulating layer 180 may be positioned on the second protective layer 160. The interlayer insulating layer 180 may cover the first drain electrode 175_1, the first source electrode 173_1, the second drain electrode 175_2, the second source electrode 173_2, and the second protective layer 160. Although it is shown in FIG. 8 that the second protective layer 160 covers all of the upper surfaces and side surfaces of the first drain electrode 175_1, the first source electrode 173_1, the second drain electrode 175_2, and the second source electrode 173_2, example embodiments are not limited thereto. In some example embodiments, at least some of the upper surfaces and side surfaces of the first drain electrode 175_1, the first source electrode 173_1, the second drain electrode 175_2, and the second source electrode 173_2 may not be covered by the second protective layer 160, and may be covered by the interlayer insulating layer 180. The interlayer insulating layer 180 may be in contact with the first drain electrode 175_1, the first source electrode 173_1, the second drain electrode 175_2, and the second source electrode 173_2. The upper surface of the second protective layer 160 may be covered by the interlayer insulating layer 180. The interlayer insulating layer 180 may be in contact with the second protective layer 160. However, example embodiments are not limited thereto, and one or more other layers may be further positioned between the interlayer insulating layer 180, and the first drain electrode 175_1, the first source electrode 173_1, the second drain electrode 175_2, the second source electrode 173_2, and the second protective layer 160.

The interlayer insulating layer 180 may be or include an insulating material. For example, the interlayer insulating layer 180 may be or include an insulating material such as SiO₂, Al₂O₃, SiN, or SiON. The interlayer insulating layer 180 may be or include the same material as that of the protective layers 140 and 160, or may be or include a material different from that of the protective layers. When the interlayer insulating layer 180 include the same material as that of the second protective layer 160, the boundary between the interlayer insulating layer 180 and the second protective layer 160 may merge. The interlayer insulating layer 180 may be or include a single layer or multiple layers.

A source bus line 530 and a drain bus line 550 may be positioned on the interlayer insulating layer 180. The source bus line 530 and the drain bus line 550 may be spaced apart from each other. The source bus line 530 and the drain bus line 550 may overlap the first drain electrode 175_1, the first gate electrode 155_1, the first source electrode 173_1, the second drain electrode 175_2, the second gate electrode 155_2, and the second source electrode 173_2 in the third direction DR3. The source bus line 530 and the drain bus line 550 may also overlap the first drift region DTR1 where the 2-dimensional electron gas 134_1 of the first channel is formed between the first source electrode 173_1 and the first drain electrode 175_1 and the second drift region DTR2 where the 2-dimensional electron gas 134_2 of the second channel is formed between the second source electrode 173_2 and the second drain electrode 175_2, in the third direction DR3. Each of the source bus line 530 and the drain bus line 550 may function as a pad for a connection with an external wiring line in order to receive an external voltage.

The second protective layer 160 may include openings, and the second source electrode 173_2 may be connected to the source bus line 530 and the first drain electrode 175_1 may be connected to the drain bus line 550, through a source contact portion 183 and a drain contact portion 185 which are positioned inside the openings of the second protective layer 160. The source contact portion 183 may be formed integrally with the source bus line 530, and the drain contact portion 185 may be formed integrally with the drain bus line 550.

The semiconductor device according to some example embodiments may further include a source bonding portion 630 that may be connected to the source bus line 530, and a drain bonding portion 650 that may be connected to the drain bus line 550. The source bonding portion 630 may be positioned on the source bus line 530. The source bonding portion 630 may be in contact with the upper surface of the source bus line 530. The source bonding portion 630 may have the shape of a water drop forming on the upper surface of the source bus line 530. The drain bonding portion 650 may be positioned on the drain bus line 550. The drain bonding portion 650 may be in contact with the upper surface of the drain bus line 550. The drain bonding portion 650 may have the shape of a water drop forming on the upper surface of the drain bus line 550.

The semiconductor device according to some example embodiments may further include a source wire portion 631 that may extend like a thread or wire from the source bonding portion 630. The source bonding portion 630 may be connected to a package source bonding portion 12 that is positioned in a ground area GA of the package substrate 10, through the source wire portion 631. Accordingly, the source bus line 530 may receive an external, desired voltage (for example, a ground voltage) through the source bonding portion 630 and transfer it to the source electrode 173. In other words, the source bus line 530 may be connected to an external circuit in a wire bonding manner. One source bus line 530 may be connected to a plurality of source bonding portions 630. The plurality of source bonding portions 630 may be arranged at predetermined intervals along the first direction DR1. Although it is shown in the drawing that the plurality of source bonding portions 630 is arranged in a line along the first direction DR1, example embodiments are not limited thereto. In some example embodiments, the plurality of source bonding portions 630 may be arranged in a zigzag manner or in any other desired pattern. In the ground area GA of the package substrate 10, a plurality of package source bonding portions 12 may be provided. The plurality of source bonding portions 630 may be connected to the plurality of package source bonding portions 12, respectively.

The semiconductor device according to some example embodiments may further include a drain wire portion 651 that may extend like a thread or wire from the drain bonding portion 650. The drain bonding portion 650 may be connected to a package drain bonding portion 14 that is positioned in a power area PA of the package substrate 10, through the drain wire portion 651. Accordingly, the drain bus line 550 may receive a predetermined or desired voltage (for example, the first power voltage VDD) externally through the drain bonding portion 650 and transfer it to the drain electrode 175. In other words, the drain bus line 550 may be connected to an external circuit in a wire bonding manner. One drain bus line 550 may be connected to a plurality of drain bonding portions 650. The plurality of drain bonding portions 650 may be arranged at predetermined or desired intervals along the first direction DR1. Although it is shown in the drawing that the plurality of drain bonding portions 650 is arranged in a line along the first direction DR1, example embodiments are not limited thereto. In some example embodiments, the plurality of drain bonding portions 650 may be arranged in a zigzag manner or in any other desired pattern. In the power area PA of the package substrate 10, a plurality of package drain bonding portions 14 may be provided. The plurality of drain bonding portions 650 may be connected to the plurality of package drain bonding portions 14, respectively.

A description of elements in FIGS. 7 and 8 that are same as or similar to elements in FIGS. 1-6, a detailed description thereof may be omitted herein for the sake of brevity.

In some example embodiments of FIGS. 7 and 8, the second source electrode 173_2 may not be connected to the substrate 110 and may be connected to the ground area GA of the package substrate 10 through the source bus line 530, the source bonding portion 630, the source wire portion 631, and the package source bonding portion 12. In some example embodiments of FIGS. 7 and 8, the second source electrode 173_2 may not include a second contact portion 173_20 which is connected to the substrate 110.

According to some example embodiments, the features of the semiconductor device of FIGS. 7 and 8 may be equally applied to the semiconductor devices according to some example embodiments of FIGS. 1 to 5, without departing from the spirit and scope disclosed herein. The second source electrode 173_2 may be connected to the substrate 110 or to the package substrate 10 depending on the package type. In a package type (for example, a dual flat no-lead package type or a transistor outline package type) in which an individual chip diced from a wafer may be packaged, the second source electrode 173_2 may be connected to the ground area GA of the package substrate 10, and in a wafer level package type in which dicing is performed after packaging is performed at wafer level, the second source electrode 173_2 may be connected to the substrate 110.

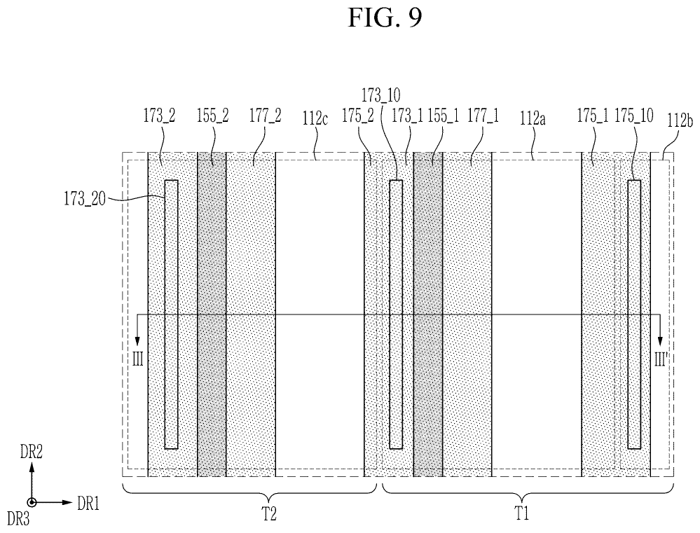

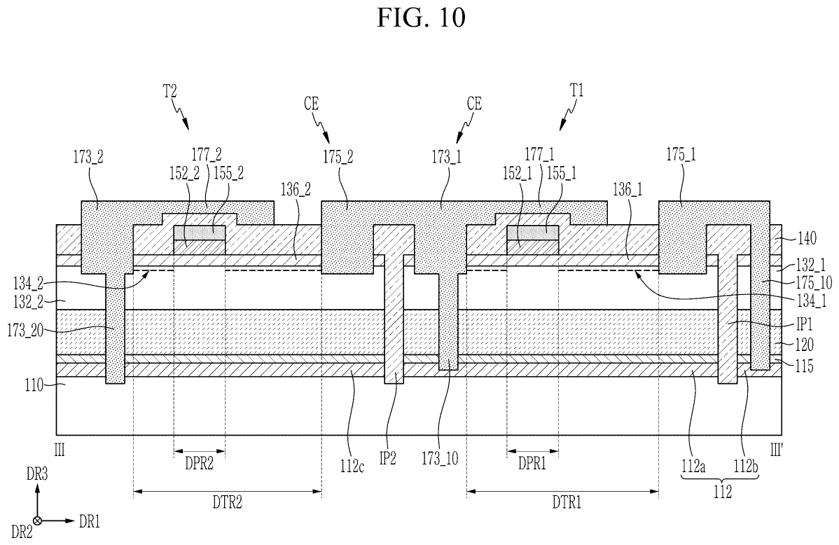

The semiconductor device in FIGS. 9 and 10 may be the same as or similar to the semiconductor device in FIGS. 1 to 4 and may be best understood with reference thereto, where like numerals indicate like elements not described again in detail.

FIG. 9 is a plan view illustrating an amplifier circuit of a semiconductor device according to some example embodiments. FIG. 10 is a cross-sectional view taken along line III-III′ of FIG. 9.

In some example embodiments of FIGS. 9 and 10, the well region 112 of the second conductivity type may be positioned between the first transistor T1 and the substrate 110 of the first conductivity type. In some example embodiments of FIGS. 9 and 10, the well region 112 may be further positioned between the second transistor T2 and the substrate 110. In some example embodiments, the first conductivity type may be a p-type, and the second conductivity type may be an n-type. In other words, the n-type well region 112 may be positioned between the p-type substrate 110 and the first transistor T1 and between the substrate 110 and the second transistor T2.

According to some example embodiments, the well region 112 may include a first well region 112a and a second well region 112b. The first well region 112a and the second well region 112b may be spaced apart or separated from each other by the first insulating pattern IP1. The first well region 112a, the second well region 112b, and the first insulating pattern IP1, are described in detail above with reference to FIGS. 1 to 4, and a detailed description thereof is omitted herein for the sake of brevity.

In some example embodiments of FIGS. 9 and 10, the well region 112 may further include a third well region 112c. The third well region 112c may be spaced apart or separated from the first well region 112a by a second insulating pattern IP2. The first well region 112a may be a portion of the well region 112 that is positioned between the first transistor T1 and the substrate 110, and the third well region 112c may be a portion of the well region 112 that is positioned between the second transistor T2 and the substrate 110. The first well region 112a may be a portion of the well region 112 which overlaps the first drift region DTR1 of the first channel layer 132_1 in the third direction DR3. The third well region 112c may be a portion of the well region 112 which overlaps the second drift region DTR2 of the second channel layer 132_2 in the third direction DR3. The first well region 112a and the second well region 112b may be separated and/or insulated by the second insulating pattern IP2.

The lower surface of the second insulating pattern IP2 may be in contact with the substrate 110. In other words, the second insulating pattern IP2 may completely pass through the well region 112 in the third direction DR3. Although it is shown in FIG. 10 that the width of the second insulating pattern IP2 in the first direction DR1 is constant, example embodiments are not limited thereto. The width of the second insulating pattern IP2 in the first direction DR1 may decrease as it goes toward the lower surface. In other words, although it is shown in FIG. 10 that the cross-sectional shapes of the second insulating pattern IP2 in the first direction DR1 and the third direction DR3 are rectangular, example embodiments are not limited thereto. As described above, the cross-sectional shapes of the second insulating pattern IP2 in the first direction DR1 and the third direction DR3 may be trapezoidal.

On both sides of the second insulating pattern IP2, the second drain electrode 175_2 and the first source electrode 173_1 may be positioned. Although it is shown in FIG. 10 that the second drain electrode 175_2 and the first source electrode 173_1 are integrally formed, example embodiments are not limited thereto. The first source electrode 173_1 and the second drain electrode 175_2 may be referred to as the common electrode CE of the first transistor T1 and the second transistor T2. The common electrode CE may cover the upper surface of the second insulating pattern IP2. The common electrode CE may surround the upper surface and both side surfaces of the second insulating pattern IP2.

For example, the first barrier layer 136_1 and the second barrier layer 136_2 may be formed as one barrier layer and then be separated by the second insulating pattern IP2. The first channel layer 132_1 and the second channel layer 132_2 may also be formed as one channel layer and then be separated by the second insulating pattern IP2.

The second insulating pattern IP2 may be formed together with the first insulating pattern IP1 and the first protective layer 140 in the same process. For example, the second insulating pattern IP2 may be formed by forming a trench so as to pass through the barrier layer including the first barrier layer 136_1 and the second barrier layer 136_2, the channel layer including the first channel layer 132_1 and the second channel layer 132_2, the buffer layer 120, the seed layer 115, and the well region 112 and filling the trench with an insulating material. Since the trenches for forming the second insulating pattern IP2 and the first insulating pattern IP1 are formed in the same etching process, the second insulating pattern IP2 may have substantially the same depth as that of the first insulating pattern IP1. The second insulating pattern IP2 may be or include the same insulating material as that of the first insulating pattern IP1 and the first protective layer 140. For example, the second insulating pattern IP2 may be or include an oxide such as SiO₂, Al₂O₃, etc. As another example, the second insulating pattern IP2 may be or include a nitride such as SiN, or an oxynitride such as SiON. The second insulating pattern IP2 may be or include a single layer or multiple layers.

The first source electrode 173_1 may include a first contact portion 173_10. The first contact portion 173_10 may be in contact with the first well region 112a. The first contact portion 173_10 may pass through the first channel layer 132_1, the buffer layer 120, and the seed layer 115 and be connected to the first well region 112a.

The second source electrode 173_2 may include a second contact portion 173_20. The second contact portion 173_20 may be in contact with the substrate 110. The second contact portion 173_20 may pass through the first channel layer 132_1, the buffer layer 120, the seed layer 115, and the third well region 112c and be connected to the substrate 110. In some example embodiments of FIGS. 9 and 10, the second contact portion 173_20 may further pass through the third well region 112c and be connected to the substrate 110.

The first drain electrode 175_1 may include a third contact portion 175_10. The third contact portion 175_10 may be in contact with the second well region 112b. The third contact portion 175_10 may pass through the first protective layer 140, the first barrier layer 136_1, the first channel layer 132_1, the buffer layer 120, and the seed layer 115, and be connected to the second well region 112b.

According to some example embodiments, the second contact portion 173_20 of the second source electrode 173_2 may be in contact with the substrate 110, and the first contact portion 173_10 of the first source electrode 173_1 and the third contact portion 175_10 of the first drain electrode 175_1 may be in contact with the well region 112 that is positioned on the substrate 110. The upper surface of the substrate 110 may be at a lower level than the upper surface of the well region 112. For example, the upper surface of the substrate 110 may be substantially at the same level as that of the lower surface of the well region 112. According to some example embodiments, the lower surface of the second contact portion 173_20 may be at a lower level than the lower surface of the first contact portion 173_10 and the lower surface of the third contact portion 175_10. The lower surface of the first contact portion 173_10 may be substantially at the same level as that of the lower surface of the third contact portion 175_10, or may be at a level different from the lower surface of the third contact portion.

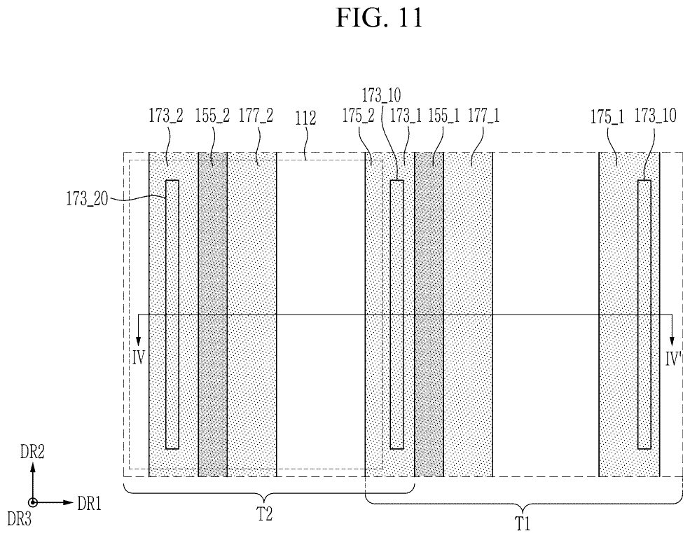

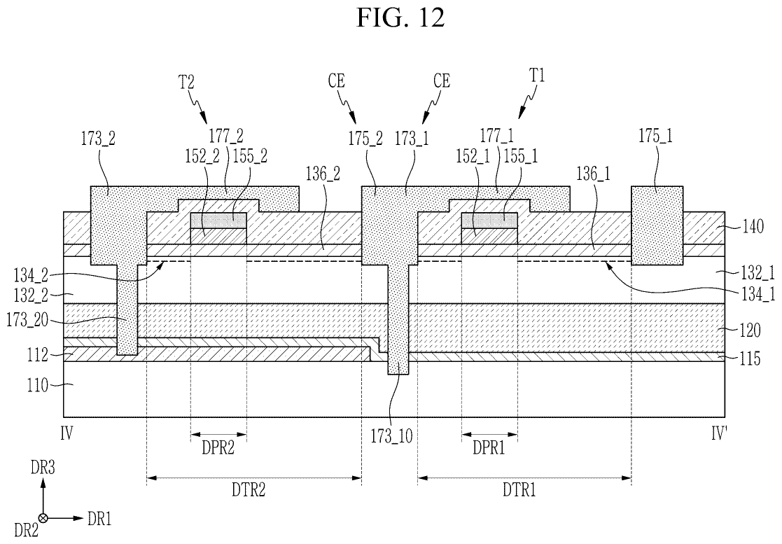

The semiconductor device in FIGS. 11 and 12 may be the same as or similar to the semiconductor device in FIG. 1-4 and may be best understood with reference thereto, where like numerals indicate like elements not described again in detail.

FIG. 11 is a plan view illustrating an amplifier circuit of a semiconductor device according to some example embodiments. FIG. 12 is a cross-sectional view taken along line IV-IV′ of FIG. 11. A detailed description of elements in FIGS. 11 and 12 that may be the same as or similar to elements in FIGS. 1 to 4 may be omitted herein for the sake of brevity.

In some example embodiments of FIGS. 11 and 12, the well region 112 of the second conductivity type may be positioned between the second transistor T2 and the substrate 110 of the first conductivity type. In some example embodiments, the first conductivity type may be an n-type, and the second conductivity type may be a p-type. In other words, the p-type well region 112 may be positioned between the n-type substrate 110 and the second transistor T2.

The substrate 110 and the well region 112 may be or include silicon. According to some example embodiments, the substrate 110 may be or include silicon doped with an n-type impurity, and the well region 112 may be or include silicon doped with a p-type impurity.

In some example embodiments of FIGS. 11 and 12, the first gate semiconductor layer 152_1, the first barrier layer 136_1, the first channel layer 132_1, the buffer layer 120, and the seed layer 115 may be positioned between the first gate electrode 155_1 and the substrate 110. Between the second gate electrode 155_2 and the substrate 110, the second gate semiconductor layer 152_2, the second barrier layer 136_2, the second channel layer 132_2, the buffer layer 120, the seed layer 115, and the well region 112 may be positioned. In other words, the well region 112 may be positioned between the second gate electrode 155_2 and the substrate 110.

The well region 112 may be positioned on the upper surface of the substrate 110. As described above, the substrate 110 may be the n-type, and the well region 112 may be the p-type. Since the upper surface of the substrate 110 and the lower surface of the well region 112, a p-n junction structure may be formed at the interface of the substrate 110 and the well region 112. In the p-n junction structure, when a reverse bias is applied, no current may flow between the well region 112 and the substrate 110.

The well region 112 may be formed through an epitaxial growth process. For example, the well region 112 may be formed by forming a silicon layer containing the p-type impurity on the entire upper surface of the n-type substrate 110 through an epitaxial process and then performing patterning on the silicon layer. Accordingly, the well region 112 may cover a portion of the upper surface of the substrate 110, and may not cover the other portion.

The seed layer 115 may be positioned on the substrate 110 and the well region 112. The seed layer 115 may cover the upper surface of the substrate 110. The seed layer 115 may cover the side surface and upper surface of the well region 112. The lower surface of the seed layer 115 may be in contact with the upper surface of the substrate 110, the side surface of the well region 112, and the upper surface of the well region 112.

In some example embodiments, the seed layer 115 may have a step profile due to the well region 112. The portion of the seed layer 115 which is positioned on the well region 112 may be positioned at a level higher than that of the portion of the seed layer 115 which is positioned directly on the substrate 110.

The buffer layer 120 may be positioned on the seed layer 115. In some example embodiments, the lower surface of the buffer layer 120 may have a step feature along the profile of the upper surface of the seed layer 115, but the upper surface of the buffer layer 120 may be relatively flat or planar.

According to some example embodiments, the second source electrode 173_2, the second gate electrode 155_2, and the common electrode CE may be positioned on the well region 112. The first gate electrode 155_1 and the first drain electrode 175_1 may be positioned offset from the well region 112. The second source electrode 173_2, the second gate electrode 155_2, and the common electrode CE may overlap the well region 112 in the third direction DR3. A portion of the common electrode CE may overlap the well region 112 in the third direction DR3, and other portions thereof may not overlap the well region 112 in the third direction DR3. The first gate electrode 155_1 and the first drain electrode 175_1 may not overlap the well region 112 in the third direction DR3. The well region 112 may overlap the second drift region DTR2 of the second channel layer 132_2 in the third direction DR3. The well region 112 may not overlap the first drift region DTR1 of the first channel layer 132_1 in the third direction DR3.

The first source electrode 173_1 may include a first contact portion 173_10. The first contact portion 173_10 may be in contact with the substrate 110. The first contact portion 173_10 may extend from the interface of the first source electrode 173_1 and the first channel layer 132_1 so as to pass through the first channel layer 132_1, the buffer layer 120, and the seed layer 115 in the third direction DR3 and be connected to the substrate 110. The first source electrode 173_1 may be connected to the substrate 110 by the first contact portion 173_10. In FIG. 12, the lower surface of the first contact portion 173_10 may be positioned at a lower level than the upper surface of the substrate 110; however, example embodiments are not limited thereto. For example, the lower surface of the first contact portion 173_10 may be positioned substantially at the same level as that of the upper surface of the substrate 110.

The second source electrode 173_2 may include a second contact portion 173_20. The second contact portion 173_20 may be in contact with the well region 112. The second contact portion 173_20 may extend from the interface of the second source electrode 173_2 and the second channel layer 132_2 so as to pass through the second channel layer 132_2, the buffer layer 120, and the seed layer 115 in the third direction DR3 and be connected to the well region 112. The second source electrode 173_2 may be connected to the well region 112 by the second contact portion 173_20. In FIG. 12, the lower surface of the second contact portion 173_20 may be positioned at a level between the upper surface and lower surface of the well region 112; however, example embodiments are not limited thereto. For example, the lower surface of the second contact portion 173_20 may be positioned substantially at the same level as that of the upper surface or lower surface of the well region 112.

According to some example embodiments, the first contact portion 173_10 of the first source electrode 173_1 may be in contact with the n-type substrate 110, and the second contact portion 173_20 of the second source electrode 173_2 may be in contact with the p-type well region 112. The first contact portion 173_10 of the first source electrode 173_1 and the second contact portion 173_20 of the second source electrode 173_2 may be in contact with layers of different conductivity types, respectively.

According to some example embodiments, the first contact portion 173_10 of the first source electrode 173_1 may be in contact with the substrate 110, and the second contact portion 173_20 of the second source electrode 173_2 may be in contact with the well region 112 that is positioned on the substrate 110. The upper surface of the substrate 110 may be at a lower level than the upper surface of the well region 112. For example, the upper surface of the substrate 110 may be substantially at the same level as that of the lower surface of the well region 112. According to some example embodiments, the lower surface of the first contact portion 173_10 may be positioned at a lower level than the lower surface of the second contact portion 173_20.

According to some example embodiments, between the first drain electrode 175_1 and the substrate 110, a well region 112 may not be positioned. Accordingly, a contact portion for connecting the first drain electrode 175_1 to a well region 112 having a conductivity type different from that of the substrate 110 (the third contact portion 175_10 in FIG. 4) may be absent.

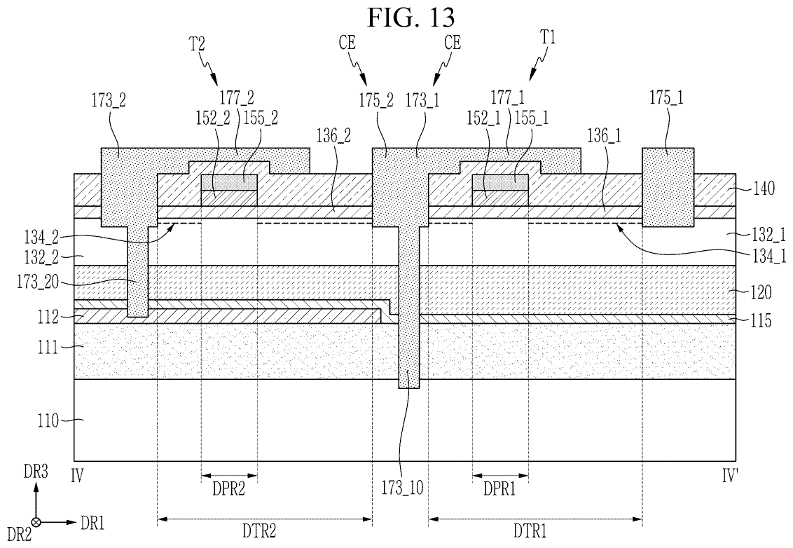

The semiconductor device in FIG. 13 may be the same as or similar to the semiconductor device in FIGS. 11 and 12 and may be best understood with reference thereto, where like numerals indicate like elements not described again in detail.

FIG. 13 is a cross-sectional view illustrating an amplifier circuit of a semiconductor device according to some example embodiments. FIG. 13 is a cross-sectional view taken along line IV-IV′ of FIG. 11.

In some example embodiments of FIG. 13, the well region 112 of the second conductivity type may be positioned between the second transistor T2 and the substrate 110 of the first conductivity type. In some example embodiments, the first conductivity type may be an n-type, and the second conductivity type may be a p-type. In other words, the p-type well region 112 may be positioned between the n-type substrate 110 and the second transistor T2.

In some example embodiments of FIG. 13, an epitaxial layer 111 may be positioned on the substrate 110. The epitaxial layer 111 may be positioned between the substrate 110 and the first transistor T1 and between the substrate 110 and the second transistor T2. According to some example embodiments, the epitaxial layer 111 may be the same first conductivity type as that of the substrate 110, and may have a lower concentration of impurities of the first conductivity type than the substrate 110. In other words, the substrate 110 may be a n⁺ Si layer, and the epitaxial layer 111 may be a n-Si layer.

According to some example embodiments, the well region 112 may be a portion of the epitaxial layer 111. For example, the entire upper surface of the epitaxial layer 111 may be doped with a p-type impurity by performing an implantation process. Subsequently, a photoresist layer may be deposited on the upper surface of the epitaxial layer 111, and a photoresist pattern may be formed through exposure and development processes. Next, a partial region of the epitaxial layer 111 may be etched using the photoresist pattern as an etch mask, whereby the well region 112 may be formed.

According to some example embodiments, the epitaxial layer 111 may include a portion of the first conductivity type and a portion of the second conductivity type, and the portion of the second conductivity type may correspond to the well region 112. The well region 112 may correspond to the region which has not been etched in the above-mentioned etching process. The upper surface of the well region 112 may be positioned at a higher level than the upper surface of the first conductivity type portion of the epitaxial layer 111. The well region 112 may have a structure protruding from the first conductivity type portion of the epitaxial layer 111.

The seed layer 115 may be positioned on the epitaxial layer 111. The seed layer 115 may cover the upper surface of the first conductivity type portion of the epitaxial layer 111. The seed layer 115 may further cover the upper surface and side surface of the well region 112. The lower surface of the seed layer 115 may be in contact with the upper surface of the first conductivity type portion of the epitaxial layer 111, the side surface of the well region 112, and the upper surface of the well region 112.

In some example embodiments, the seed layer 115 may have a step profile due to the well region 112. The portion of the seed layer 115 that is positioned on the well region 112 may be at a higher level than the portion of the seed layer 115 that is on the first conductivity type portion of the epitaxial layer 111.

The buffer layer 120 may be positioned on the seed layer 115. In some example embodiments, the lower surface of the buffer layer 120 may have a step feature along the profile of the upper surface of the seed layer 115, but the upper surface of the buffer layer 120 may be relatively flat or planar.

In some example embodiments of FIG. 13, the first contact portion 173_10 of the first source electrode 173_1 may pass through the epitaxial layer 111 and be connected to the substrate 110. In some example embodiments, the first contact portion 173_10 may extend from the interface of the first source electrode 173_1 and the first channel layer 132_1 so as to pass through the first channel layer 132_1, the buffer layer 120, the seed layer 115, and the epitaxial layer 111 in the third direction DR3 and be connected to the substrate 110. In some example embodiments of FIG. 13, the first contact portion 173_10 may further pass through the epitaxial layer 111.

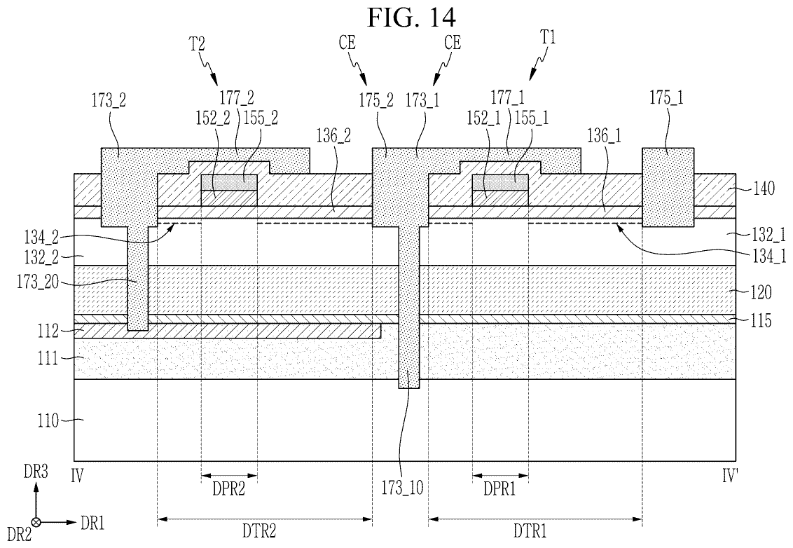

The semiconductor device in FIG. 14 may be the same as or similar to the semiconductor device in FIG. 13 and may be best understood with reference thereto, where like numerals indicate like elements not described again in detail.

FIG. 14 is a cross-sectional view illustrating an amplifier circuit of a semiconductor device according to some example embodiments. FIG. 14 is a cross-sectional view taken along line IV-IV′ of FIG. 11.

In some example embodiments of FIG. 14, an epitaxial layer 111 may be positioned on the substrate 110. The epitaxial layer 111 may be positioned between the substrate 110 and the first transistor T1 and between the substrate 110 and the second transistor T2. According to some example embodiments, the epitaxial layer 111 may be the same first conductivity type as that of the substrate 110, and may have a lower concentration of impurities of the first conductivity type than the substrate 110. In other words, the substrate 110 may be a n⁺ Si layer, and the epitaxial layer 111 may be a n Si layer.

According to some example embodiments, the well region 112 may be a portion of the epitaxial layer 111. According to some example embodiments, the well region 112 may be positioned between the second transistor T2 and the substrate 110.

For example, a photoresist layer may be deposited on the epitaxial layer 111, and a photoresist pattern may be formed through exposure and development processes. The well region 112 may be formed by doping the upper surface of the epitaxial layer 111, which is exposed and not covered by the photoresist pattern, with an n-type impurity through an implantation process.

According to some example embodiments, the epitaxial layer 111 may include a portion of the first conductivity type and a portion of the second conductivity type, and the portion of the second conductivity type may correspond to the well region 112. In some example embodiments of FIG. 14, the upper surface of the well region 112 may be positioned substantially at the same level as that of the upper surface of the first conductivity type portion of the epitaxial layer 111. The well region 112 may have a structure buried in the upper surface of the epitaxial layer 111. The side surface and lower surface of the well region 112 may be surrounded by the first conductivity type portion of the epitaxial layer 111.

The seed layer 115 may be positioned on the epitaxial layer 111. The seed layer 115 may cover the upper surface of the first conductivity type portion of the epitaxial layer 111 and the upper surface of the well region 112. The lower surface of the seed layer 115 may be in contact with the upper surface of the first conductivity type portion and the upper surface of the well region 112.

In some example embodiments, the seed layer 115 may be relatively flat or planar. Since the upper surface of the well region 112 and the upper surface of the first conductivity type portion of the epitaxial layer 111 are substantially at the same level, the seed layer 115 may be relatively flat or planer. The portion of the seed layer 115 that is positioned on the first conductivity type portion of the epitaxial layer 111 and the portion of the seed layer 115 that is positioned on the well region 112 may be substantially at the same level.

The buffer layer 120 may be positioned on the seed layer 115. In some example embodiments, the lower surface of the buffer layer 120 may be relatively flat or planar along the profile of the upper surface of the seed layer 115.

While several example embodiments have been provided in the present disclosure, it should be understood that the disclosed systems and methods might be embodied in many other specific forms without departing from the spirit or scope of the present disclosure. The present examples embodiments are to be considered as illustrative and not restrictive, and the intention is not to be limited to the details given herein. For example, the various elements or components may be combined or integrated in another system or certain features may be omitted, or not implemented.

In addition, techniques, systems, subsystems, and methods described and illustrated in the various example embodiments as discrete or separate may be combined or integrated with other systems, modules, techniques, or methods without departing from the scope of the present disclosure. Other items shown or discussed as coupled or directly coupled or communicating with each other may be indirectly coupled or communicating through some interface, device, or intermediate component whether electrically, mechanically, or otherwise. Other examples of changes, substitutions, and alterations are ascertainable by one skilled in the art and could be made without departing from the spirit and scope disclosed herein.

What is claimed is:

1. A semiconductor device comprising:
a substrate of a first conductivity type;
a first transistor and a second transistor on the substrate; and
a well region that is between at least one of the first transistor and the second transistor, and the substrate, and has a second conductivity type different from the first conductivity type, wherein
the first transistor includes:
a first channel layer on the substrate;
a first barrier layer on the first channel layer;
a first gate electrode on the first barrier layer; and
a first source electrode and a first drain electrode that are on opposite sides of the first gate electrode, and are connected to the first channel layer, the second transistor includes:
a second channel layer on the substrate;
a second barrier layer on the second channel layer;
a second gate electrode on the second barrier layer; and
a second source electrode and a second drain electrode that are on opposite sides of the second gate electrode, and are connected to the second channel layer,
the first drain electrode is connected to a first power voltage, and the second source electrode is connected to a second power voltage, and wherein the first source electrode and the second drain electrode are connected to each other, and
at least one of the first source electrode and the second source electrode is connected to the well region.

2. The semiconductor device of claim 1, wherein:
the first power voltage is higher than the second power voltage,
the well region is between the first transistor and the substrate, and
the first source electrode is connected to the well region.

3. The semiconductor device of claim 2, wherein:
the first conductivity type is a p-type, and
the second conductivity type is an n-type.

4. The semiconductor device of claim 3, wherein:
the second source electrode is connected to the substrate.

5. The semiconductor device of claim 4, wherein:
the first source electrode includes a first contact portion that contacts the well region,
the second source electrode includes a second contact portion that contacts the substrate, and
a lower surface of the second contact portion is at a lower level than a lower surface of the first contact portion.

6. The semiconductor device of claim 3, wherein:
the well region includes a first well region between the substrate and the first gate electrode, and a second well region spaced apart from the first well region,
the semiconductor device further includes a first insulating pattern between the first well region and the second well region, and
the first drain electrode is connected to the second well region.

7. The semiconductor device of claim 3, wherein:
the well region is between the substrate and the second transistor,
the well region includes a third well region between the first gate electrode and the substrate, and a fourth well region between the second gate electrode and the substrate, and
the semiconductor device further includes a second insulating pattern between the third well region and the fourth well region.

8. The semiconductor device of claim 7, wherein:
the second source electrode includes a third contact portion that passes through the fourth well region and is in contact with the substrate.

9. The semiconductor device of claim 3, further comprising:
an epitaxial layer of the first conductivity type between the substrate and the first transistor and between the substrate and the second transistor, wherein
the epitaxial layer has a lower concentration of impurities of the first conductivity type than the substrate, and
the well region is a portion of the epitaxial layer.

10. The semiconductor device of claim 9, wherein:
the second source electrode passes through the epitaxial layer and is connected to the substrate.

11. The semiconductor device of claim 3, further comprising:
a package substrate and a source wire portion, wherein
the substrate is on the package substrate, and
the source wire portion electrically connects the package substrate and the second source electrode.

12. The semiconductor device of claim 1, wherein:
the first power voltage is higher than the second power voltage,
the well region is between the second transistor and the substrate, and
the second source electrode is connected to the well region.

13. The semiconductor device of claim 12, wherein:
the first conductivity type is an n-type, and
the second conductivity type is a p-type.

14. A semiconductor device comprising:
a substrate of a first conductivity type;
a first transistor and a second transistor on the substrate; and
a well region that is between the substrate and the first transistor, and has a second conductivity type different from the first conductivity type, wherein
the first transistor includes:
a first channel layer on the substrate;
a first barrier layer on the first channel layer;
a first gate electrode on the first barrier layer; and
a first source electrode and a first drain electrode that are on opposite sides of the first gate electrode, and are connected to the first channel layer,
the second transistor includes:
a second channel layer on the substrate;
a second barrier layer on the second channel layer;
a second gate electrode on the second barrier layer; and
a second source electrode and a second drain electrode that are on opposite sides of the second gate electrode, and are connected to the second channel layer, and
the first drain electrode is connected to a first power voltage, and the second source electrode is connected to a second power voltage lower than the first power voltage, and wherein the first source electrode and the second drain electrode are connected to the well region.

15. The semiconductor device of claim 14, wherein:
the first conductivity type is a p-type, and
the second conductivity type is an n-type.

16. The semiconductor device of claim 15, wherein:
the second source electrode is connected to the substrate.

17. The semiconductor device of claim 15, wherein:
the well region is between the substrate and the second transistor,
the well region includes a first well region between the substrate and the first transistor, and a second well region between the substrate and the second transistor, and
the semiconductor device further includes an insulating pattern between the first well region and the second well region.

18. The semiconductor device of claim 15, further comprising:
an epitaxial layer between the substrate and the first transistor and between the substrate and the second transistor, wherein
the epitaxial layer includes a portion of the first conductivity type having a lower concentration of impurities of the first conductivity type than the substrate, and a portion of the second conductivity type, and
the portion of the second conductivity type is the well region.

19. A semiconductor device comprising:
a substrate of a first conductivity type;
a first transistor and a second transistor on the substrate; and
a well region that is between the substrate and the first transistor and has a second conductivity type different from the first conductivity type, wherein
the first transistor includes:
a first channel layer on the substrate;
a first barrier layer on the first channel layer;
a first gate electrode on the first barrier layer; and
a first source electrode and a first drain electrode that are on opposite sides of the first gate electrode, and are connected to the first channel layer,
the second transistor includes:
a second channel layer on the substrate;
a second barrier layer on the second channel layer;
a second gate electrode on the second barrier layer; and
a second source electrode and a second drain electrode that are on opposite sides of the second gate electrode, and are connected to the second channel layer,
the first drain electrode is connected to a first power voltage, and the second source electrode is connected to a second power voltage lower than the first power voltage, and wherein the first source electrode and the second drain electrode are connected to each other,
the well region includes a first well region between the substrate and the first source electrode and a second well region between the substrate and the first drain electrode, and wherein the first well region and the second well region are spaced apart from each other, and
the first source electrode is connected to the first well region, and the first drain electrode is connected to the second well region.

20. The semiconductor device of claim 19, wherein:
the second source electrode is connected to the substrate.
